(19) United States
(12) Patent Application Publication
(10) Pub. No.: US 2025/0358978 A1
(43) Pub. Date: Nov. 20, 2025

(54) COOLANT DISTRIBUTION UNIT AND METHOD

(71) Applicant: Baltimore Aircoil Company, Inc., Jessup, MD (US)

(72) Inventors: Jian Xu, Ellicott City, MD (US); Yohann Lilian Rousselet, Baltimore, MD (US); David Andrew Aaron, Reisterstown, MD (US); Frank Morrison, Crownsville, MD (US); Lukas Rubino, Waxhaw, NC (US)

(21) Appl. No.: 19/213,262

(22) Filed: May 20, 2025

Related U.S. Application Data
(60) Provisional application No. 63/649,574, filed on May 20, 2024.

(51) Int. Cl. H05K 7/20

(52) U.S. Cl. CPC H05K 7/2079; H05K 7/20836

(57) ABSTRACT

In one aspect, a coolant distribution unit (CDU) for cooling a process fluid of a technical loop including computers. The CDU includes a heat exchanger configured to transfer heat from the technical loop process fluid to a process fluid of a facility loop. The CDU includes a rapid response cooling apparatus operatively connected to the heat exchanger. The CDU includes a controller configured to determine a surge of a cooling load of the computers based at least in part upon data from a sensor of the technical loop. The controller is configured to cause the rapid response cooling apparatus to contribute to satisfying the cooling load of the computers based at least in part upon the surge of the cooling load of the computers.

### CROSS-REFERENCE TO RELATED APPLICATION

This application claims the benefit of U.S. Provisional Patent App. No. 63/649,574, filed May 20, 2024, which is hereby incorporated by reference herein.

### TECHNICAL FIELD

This disclosure relates to systems for removing heat from a process fluid and, more specifically, relates to systems for liquid-cooled industrial processes such as computer data centers.

### BACKGROUND

A conventional heat transfer system for a liquid-cooled or a liquid assisted, air-cooled computer datacenter has a facility cooling system loop (hereafter “facility loop”) that utilizes water, or a glycol mixture such as propylene glycol or ethylene glycol, and a technology cooling system loop (hereafter “technical loop”) that utilizes water, a glycol mixture such as propylene glycol, or a dielectric fluid. The technical loop includes a heat source such as a row of racks of server computers and one side of a heat exchanger of a coolant distribution unit (CDU). The facility loop includes another side of the heat exchanger of the CDU, a chiller, and a cooling tower. Other heat rejection apparatuses may be utilized in the facility loop, such as a water-cooled chiller with fluid coolers, an air-cooled chiller, an open cooling tower, or a fluid cooler.

The heat exchanger of the CDU transfers heat from the working fluid, such as a glycol mixture, in the technical loop to the fluid the facility loop. The chiller and cooling tower of the facility loop remove heat from the water of the facility loop. The computers of the technical loop require the glycol to be within a predetermined temperature range to keep the computers from overheating.

One issue with the conventional heat transfer system is a sudden increase in energy usage by the computers of the technical loop, such as due to the computers implementing a processor-intensive algorithm such as an artificial intelligence (AI) algorithm which may result in the temperature of the glycol exceeding the predetermined temperature range required by the computers before the cooling tower and chiller of the facility loop can provide sufficiently cool water to the CDU. When this sudden load increase occurs, a temperature spike also occurs and the facility loop may take a period of time, such as five minutes, before sufficiently cool water is available to cool the CDU.

### SUMMARY

In one aspect of the present disclosure, a coolant distribution unit (CDU) is provided for cooling a process fluid of a technical loop including computers. The coolant distribution unit includes a heat exchanger configured to transfer heat from the technical loop process fluid to a process fluid of a facility loop. The CDU includes a rapid response cooling apparatus operatively connected to the heat exchanger. The CDU includes a controller configured to determine a surge of a cooling load of the computers based at least in part upon data from a sensor of the technical loop. The controller is configured to cause the rapid response cooling apparatus to contribute to satisfying the cooling load of the computers based at least in part upon the surge of the cooling load of the computers. In this manner, the rapid response cooling apparatus may satisfy the increased cooling load of the computers of the technical loop until the facility loop has sufficient capacity to handle the increased cooling load of the computers. For example, the rapid response cooling apparatus may provide sufficient cooling capacity for a predetermined period of time, such as five to ten minutes, until the chiller(s) or other components of the facility loop can adequately cool the facility loop process fluid to enable the heat exchanger to satisfy the increased cooling load of the computers.

The sensor may be configured to detect, for example, at least one of a temperature parameter and an electrical consumption parameter (e.g., current or power draw) of the technical loop. The controller may use the data from the sensor to determine the surge of the cooling load of the computers before the increased-temperature technical loop process fluid reaches the heat exchanger. This provides a lead time for the rapid response cooling apparatus to begin contributing to resolving the surge of the cooling load of the computers and keep the technical loop process fluid from exceeding a predetermined maximum temperature, e.g., 35° C.

The present disclosure also provides a method of operating a cooling distribution unit including a heat exchanger and a rapid response cooling apparatus. The heat exchanger is configured to transfer heat from a process fluid of a technical loop including computers to a process fluid of a facility loop. The method includes detecting a sudden increase of a cooling load of the computers and causing the rapid response cooling apparatus to contribute to satisfying the increased cooling load of the computers. The method further includes reducing the contribution of the rapid response cooling apparatus to satisfying the cooling load of the computers upon the facility loop being able to satisfy the increased cooling load. Reducing the contribution of the rapid response cooling apparatus may include, for example, reducing the contribution of the rapid response cooling apparatus after a predetermined period of time and/or reducing the contribution in response to the facility loop providing facility loop process fluid at or below a predetermined minimum temperature.

In one embodiment, the facility loop requires a period of time of at least two minutes (e.g., 2-10 minutes) following the sudden increase in the cooling load of the computers before the facility loop is able to catch-up and satisfy the increased cooling load. In this embodiment, causing the rapid response cooling apparatus to contribute to satisfying the sudden increase of the cooling load of the computers comprises causing the rapid response cooling apparatus to contribute to satisfying the sudden increase of the cooling load for at least the period of time.

In one embodiment, the facility loop has a normal operating condition and a reduced operating condition. The heat exchanger facilitates a first rate of heat exchange between the technical loop process fluid and the facility loop process fluid when the facility loop is in the normal operation condition that is greater than a second rate of heat exchange between the technical loop process fluid and the facility loop process fluid when the facility loop is in the reduced operating condition. In this embodiment, causing the rapid response cooling apparatus to contribute to satisfying the increased cooling load of the computers comprises causing the rapid response cooling apparatus to contribute to satisfying the increased cooling load while the facility loop is in the reduced operating condition.

### BRIEF DESCRIPTION OF DRAWINGS

FIG. 1 is a schematic representation of a heat transfer system for removing heat from computer racks of a computer datacenter;

FIG. 2A is a schematic representation of a coolant distribution unit (CDU) with a rapid response cooling apparatus including a thermal energy storage;

FIG. 2B is a schematic representation of a CDU with a rapid response cooling apparatus including a chiller;

FIG. 3 is a schematic representation of a CDU with a chiller and a rapid response cooling apparatus including a thermal energy storage;

FIG. 4A is a schematic representation of a CDU having a phase change material (PCM) thermal energy storage (TES) downstream of a heat exchanger of the CDU showing the CDU cooling the computer racks while being in a PCM TES charge mode;

FIG. 4B is schematic representation of the CDU of FIG. 4A showing the CDU in a PCM TES discharge mode to cool the computer racks;

FIG. 5A is a schematic representation of a CDU having a PCM TES and a bypass, FIG. 5A showing the CDU in a PCM TES charge mode while cooling the computer racks;

FIG. 5B is a schematic representation of the CDU of FIG. 5A showing the CDU in a PCM TES bypass mode while cooling the computer racks;

FIG. 5C is a schematic representation of the CDU of FIG. 5A showing the CDU in a PCM TES discharge mode to cool the computer racks;

FIG. 5D is a schematic representation of a CDU having a PCM TES, a PCM TES bypass, and a cooling load bypass, FIG. 5D showing the CDU in a PCM TES charge mode with full cooling load bypass;

FIG. 5E is a schematic representation of the CDU of FIG. 5D showing the CDU in a PCM TES bypass mode while cooling the computer racks;

FIG. 5F is a schematic representation of the CDU of FIG. 5D showing the CDU in a PCM TES hybrid discharge mode while cooling the computer racks;

FIG. 5G is a schematic representation of the CDU of FIG. 5D showing the CDU in a PCM hybrid charge mode while cooling the computer racks;

FIG. 5H is a schematic representation of the CDU of FIG. 5D showing the CDU in a PCM TES discharge mode while cooling the computer racks;

FIGS. 5I and 5J are a flow diagram of a method of operating the CDU of FIG. 5D;

FIG. 6A is a schematic representation of a CDU having a PCM TES and a secondary heat exchanger operable to recharge the PCM TES using chilled water from the facility loop, FIG. 6A showing the CDU in a PCM TES charge mode while cooling the computer racks with a primary heat exchanger of the CDU;

FIG. 6B is a schematic representation of the CDU of FIG. 6A showing the CDU in a PCM TES discharge mode to cool the computer racks;

FIG. 6C is a schematic representation similar to FIG. 6B showing the facility loop providing chilled water to the primary heat exchanger of the CDU;

FIG. 7A is a schematic representation of a CDU having a PCM TES and a secondary heat exchanger with a dedicated heat rejection apparatus, FIG. 7A showing the CDU in a PCM TES charge mode while cooling the computer racks with a heat exchanger of the CDU;

FIG. 7B is a schematic representation of the CDU of FIG. 7A showing the CDU in a PCM TES discharge mode to cool the computer racks;

FIG. 7C is a schematic representation of a CDU having a PCM TES and a dedicated heat rejection apparatus, FIG. 7C showing the CDU in a PCM charge mode while cooling the racks;

FIG. 7D is a schematic representation of the CDU of FIG. 7C showing the CDU in a PCM TES discharge mode with the dedicated heat rejection apparatus providing supplemental cooling;

FIG. 8A is a schematic representation of a CDU having a PCM TES and a chiller that utilizes water from a facility loop, FIG. 8A showing the CDU in a PCM TES charge mode while cooling the computer racks using the heat exchanger;

FIG. 8B is a schematic representation of the CDU of FIG. 8A showing the CDU in a PCM TES discharge mode to cool the computer racks;

FIG. 8C is a schematic representation of the CDU of FIG. 8A but with a booster chiller instead of a PCM TES;

FIG. 9A is a schematic representation of a CDU having a PCM TES and a chiller with a dedicated heat rejection apparatus, FIG. 9A showing the CDU in a PCM TES charge mode with the dedicated heat rejection apparatus charging the PCM TES while the heat exchanger cools the computer racks;

FIG. 9B is a schematic representation of the CDU of FIG. 9A showing the CDU in a PCM TES discharge mode to cool the computer racks;

FIG. 9C is a schematic representation of a CDU having a PCM TES and an air-cooled chiller, FIG. 9C showing the CDU in a PCM TES charge mode with the air-cooled chiller charging the PCM TES and the heat exchanger cooling the computer racks;

FIG. 9D is a schematic representation of the CDU of FIG. 9C showing the CDU in a PCM TES discharge mode to cool the computer racks;

FIG. 9E is a schematic representation of a CDU having a PCM TES, a chiller, and a dedicated heat rejection apparatus inside of the CDU, FIG. 9E showing the CDU in a PCM charge mode with the dedicated heat rejection apparatus and chiller charging the PCM TES and the heat exchanger cooling the computer racks;

FIG. 9F is a schematic representation of the CDU of FIG. 9E showing the CDU in a PCM TES discharge mode;

FIG. 10A is a schematic representation of a CDU having an internal-melt ice TES and a chiller that utilizes chilled water from a facility loop, FIG. 10A showing the CDU in an ice TES charge mode while a heat exchanger of the CDU cools the computer racks;

FIG. 10B is a schematic representation of the CDU of FIG. 10A showing the CDU in an ice TES discharge mode with the ice TES cooling the computer racks;

FIG. 11A is a schematic representation of a CDU having an external-melt ice TES, a chiller, and a secondary heat exchanger to decouple the glycol mixture of the technical loop from the water of the ice TES, FIG. 11A showing the CDU in an ice TES charge mode while the heat exchanger cools the computer racks;

FIG. 11B is a schematic representation of the CDU of FIG. 11A showing the CDU in an ice TES discharge mode;

FIG. 11C is a schematic representation of a CDU for a technical loop that utilizes water, FIG. 11C showing the CDU in a TES charge mode;

FIG. 11D is a schematic representation of the CDU of FIG. 11C showing the CDU in a TES discharge mode;

FIG. 12A is a schematic representation of CDU having an external melt ice TES of the facility loop and a dedicated chiller to recharge the ice TES, FIG. 12A showing the CDU in an ice TES charge mode to provide cooling for the heat exchanger that cools the computer racks;

FIG. 12B is a schematic representation of the CDU of FIG. 12A showing the CDU in an ice TES discharge mode to cool the computer racks;

FIG. 13A is a schematic representation of a CDU having a PCM TES of the facility loop, FIG. 13A showing the CDU in a PCM TES charge mode while the heat exchanger cools the computer racks; and

FIG. 13B is a schematic representation of the CDU of FIG. 13A showing the CDU in a PCM TES discharge mode to provide cooling for the heat exchanger that cools the computer racks.

### DETAILED DESCRIPTION

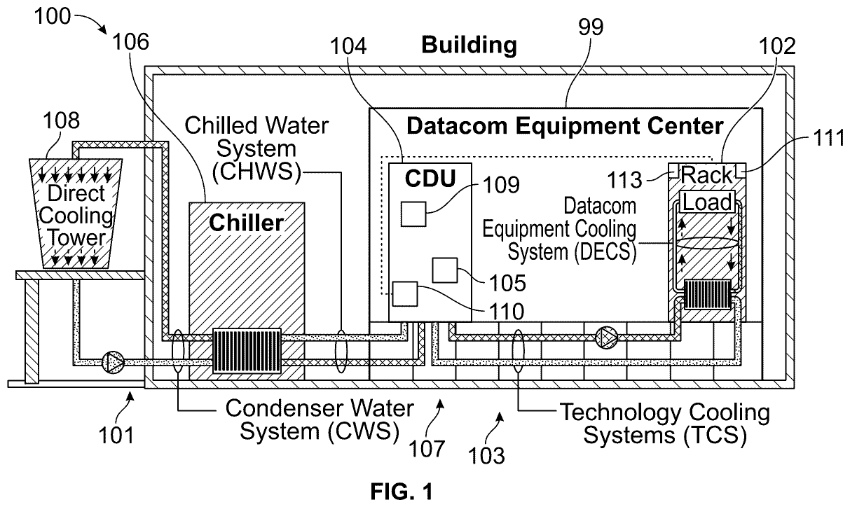

Regarding FIG. 1, a heat transfer system 100 is provided for an industrial process such as cooling a computer data center. The heat transfer system 100 has a process fluid heat exchange circuit 107 that includes a primary loop, such as a facility loop 101, and a secondary loop, such as a technical loop 103. The technical loop 103 includes one or more electronic components such as computers, servers, and electronic data storage. The electronic components are stored in racks 102 (also referred to herein as computer racks), such as inside a building of the data center. The process fluid heat exchange circuit 107 of the heat transfer system 100 has a heat transfer apparatus, such as coolant distribution unit (CDU) 104 with one or more primary heat exchangers 105 for transferring heat between a first process fluid of the technical loop 103, such as a glycol mixture, that absorbs heat from the electronic components of the racks 102 and a second process fluid of the facility loop 101, such as water, that discharges heat via a chiller 106 and a heat rejection apparatus such as a cooling tower 108. The heat transfer system 100 may be utilized for liquid cooled data centers (e.g., using cold plates, immersion cooling as well as liquid-assisted, air-cooled data centers (e.g., air-cooled racks with rear-door heat exchangers).

The CDU 104 has a thermal energy storage such as a phase change material (PCM) thermal energy storage (TES) 109 that utilizes sensible heat transfer to cool the process fluid of the technical loop 103. More specifically, the PCM TES 109 has a phase change material that melts to absorb heat from the process fluid of the technical loop 103. Examples of phase change material of the PCM TES 109 include paraffin waxes, non-paraffin organics, hydrated salts, or metallic materials. Alternatively or additionally, the thermal energy storage may include a shape memory alloy and/or a shape-responsive metamaterial as some examples.

The heat transfer system 100 may have one or more thermal energy storage devices, such as ice or PCM, for each CDU 104. Conversely, the heat transfer system 100 may have a plurality of CDUs 104 connected to a single thermal energy storage device, such as in embodiments described below that utilize a TES chiller. The plurality of CDUs 104 may be operated independently of one another if a diversity factor is desired. Each of the plurality of CDUs 104 may serve one or more rows of computer racks 102. Further, the thermal energy storage device may be sized to shift large cooling requirements to off-peak demand time periods if desired for a particular embodiment.

The heat transfer system 100 has a controller 110 operable to change the process fluid heat exchange circuit 107 between different operating modes including a PCM TES charge mode and a PCM TES discharge mode based at least in part upon data from PCM inventory sensor(s) of the PCM TES 109 and the cooling load required by the computer racks 102. The PCM of the CDU 104 is able to handle spikes in heat load from computer racks 102 for short durations, for example for 5 minutes until the chiller can ramp up and catch up to the heat load spike. Utilizing PCM for this short duration allows the sizing of the PCM storage to be reasonably small and to be contained within the CDU 104 inside the equipment center 99. The PCM TES 109 is designed and sized such that the PCM TES 109 can be recharged within a few hours so that surges in required cooling load can be handled several times a day to handle load spikes.

In one embodiment, the PCM TES 109 is configured to provide the heat transfer system 100 with enough capacity for emergency cooling during a 20- to 30-minute period while a chiller restarts. In another embodiment, the PCM TES 109 may be configured to provide one to four hours of either full or partial load shaving storage for load shifting during a time of day where there is a high electricity cost or demand charge. The controller 110 may have control logic with different modes to facilitate the process fluid heat exchange circuit 107 of the heat transfer system 100 providing cooling for load spikes, emergency cooling, and/or load shifting.

The computer racks 102 each have one or more sensors, such as electrical energy load sensors 111, that are connected to the controller 110 of the CDU 104. The energy load sensor 111 may be a kW sensor and detects when the electrical power draw of each computer rack 102 spikes. As another example, the energy load sensor 111 may be a current draw sensor. Alternatively or additionally, the computer racks 102 each have a temperature sensor 113 connected to the controller 110. The temperature sensor 113 detects electronic device temperature and/or rack output glycol temperature to permit the controller 110 to detect that the head load from the computer rack 102 is spiking. As another example, the temperature sensor 113 may detect a temperature of air that is heated by operation of the computers. The sooner the controller 110 detects the spike in energy consumption and/or heat load via the sensors 111, 113, the sooner the controller 110 can change the CDU 104 to a TES discharge mode. The TES discharge mode can assist the primary heat exchanger 105 as the facility loop 101 is ramping up or can run without cooling from the primary heat exchanger 105 during load shaving periods.

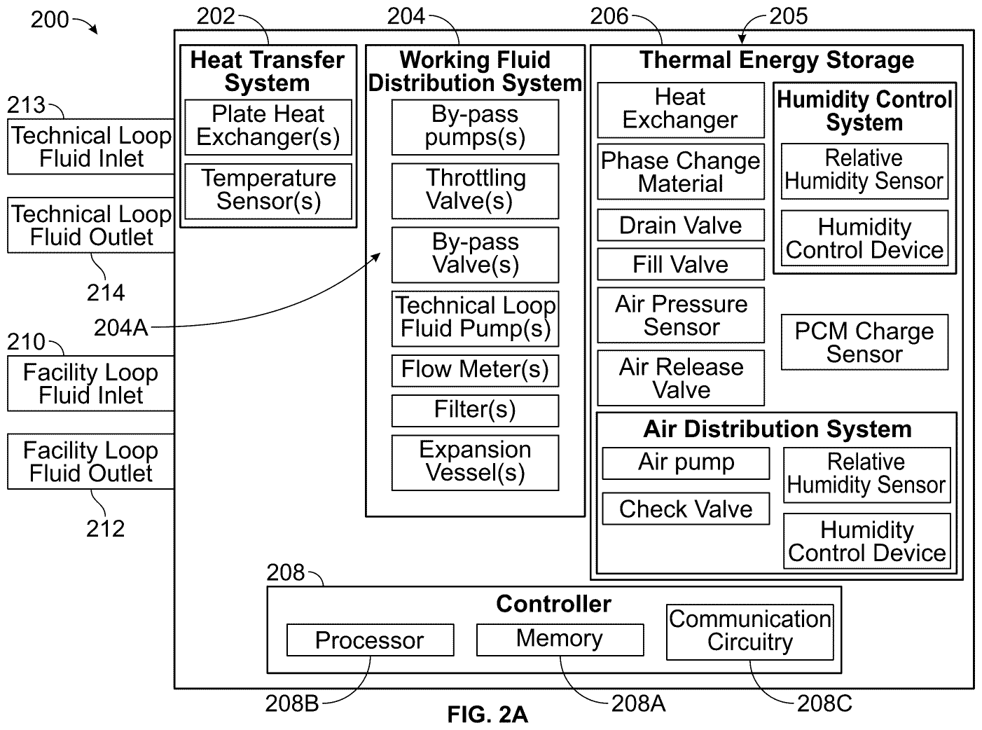

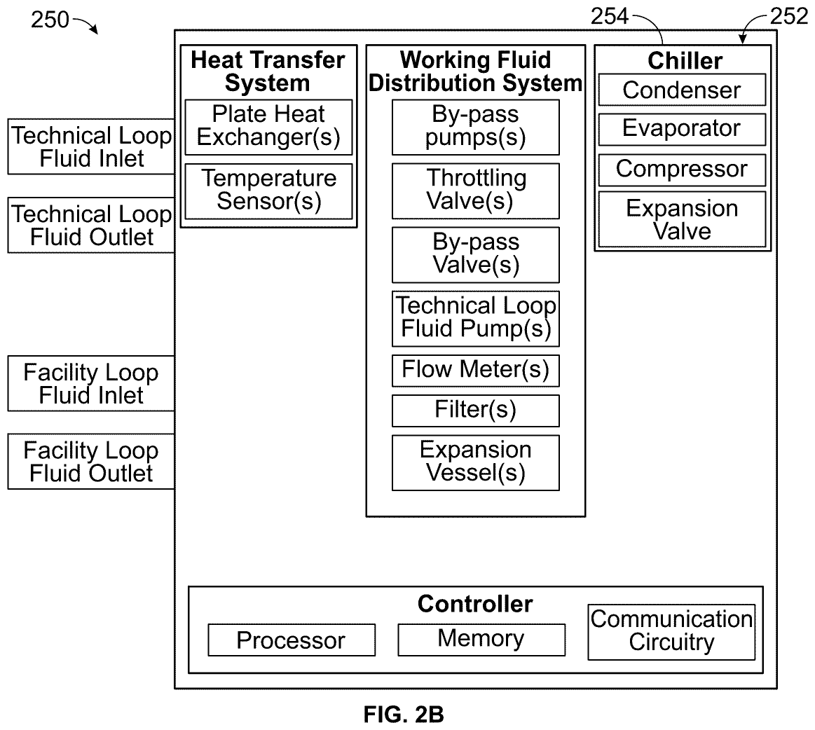

Regarding FIG. 2A, a CDU 200 is provided that is one embodiment of the CDU 104. The CDU 200 is a packaged CDU and lacks a chiller. The CDU 200 includes a heat transfer system 202, a working fluid distribution system 204, a rapid response cooling apparatus 205 such as a thermal energy storage 206, and a controller 208. The working fluid distribution system 204 may include one or more flow control devices 204A, such as pumps and/or valves, operable to direct process fluid in the technical loop 103 and change a flow rate of the process fluid in the technical loop 103. The working fluid distribution system 204 may further include one or more filters to filter the process fluid in the technical loop 103. The CDU further includes a facility loop fluid inlet 210, a facility loop fluid outlet 212, a technical loop fluid inlet 210, a technical loop fluid inlet 213, and a technical loop fluid outlet 214.

The controller 208 includes a non-transitory computer readable memory 208A, such as RAM, ROM, or a hard drive, operable to store computer-readable data (e.g., computer code) thereon. The controller 208 includes a processor 208B, such as a microprocessor or an application-specific integrated circuit, operable to utilize the data stored in the memory 208A to perform one or more of the methods described herein. The controller 208 further includes communication circuitry 208C to communicate via wired and/or wireless approaches with components of the CDU 200 and/or external devices. In one embodiment, the communication circuitry 208C includes a network interface operable to communicate data over a network such as an intranet and/or the internet as some examples.

Regarding FIG. 2B, a CDU 250 is provided that is another embodiment of the CDU 104 and is similar to the CDU 200. One difference between the CDU 200 and the CDU 250 is that the CDU 250 has a rapid response cooling apparatus 252 that includes a chiller 254. The chiller 254 is smaller than the chiller(s) of the facility loop 101 and can start up quickly to provide temporary cooling for the technical loop 103 while the larger chiller(s) of the facility loop 101 ramp up operation. For example, the chiller 254 may have a capacity of approximately 20 tons, while the chiller(s) of the facility loop may have a capacity of approximately 3,000 tons. In another embodiment, the rapid response cooling apparatus 252 may include a heat pump.

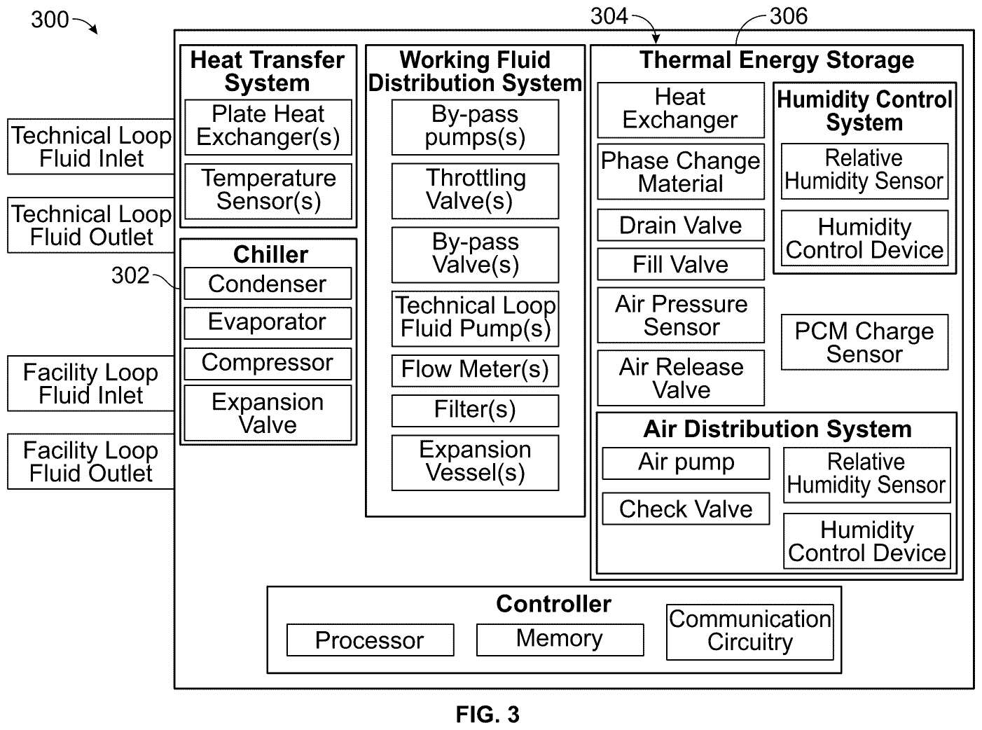

Regarding FIG. 3, a CDU 300 is provided that is another embodiment of the CDU 104 and is similar to the CDU 200. One difference between the CDU 200 and the CDU 300 is that the CDU 300 has a chiller 302 and a rapid response cooling apparatus 304 that includes a thermal energy storage 306.

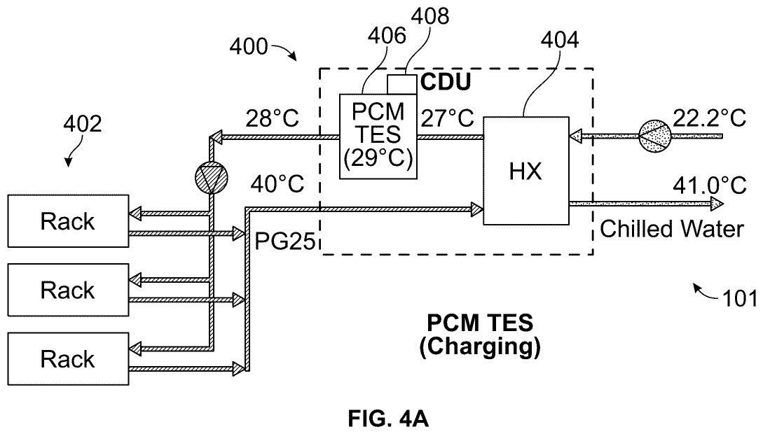

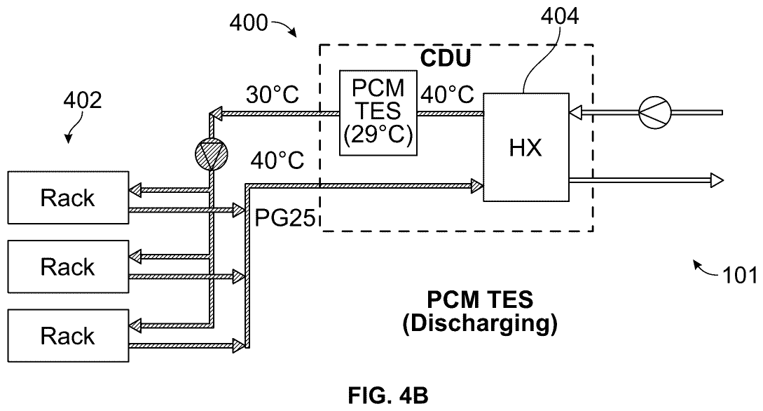

FIGS. 4A-11C provide further embodiments of the CDU 104 and show the embodiments of the CDU 104 in the technical loop 103. The type of working fluid and working temperatures shown in the drawings are selected for the particular configuration of a given data center. For example, water may be utilized as the process fluid in the technical loop 103 to remove heat from computer racks 402. As a further example, the melt and freeze temperatures of the PCM device utilized in the system 100 are selected to provide the desired performance for a particular data center.

With reference to FIGS. 4A-4B, CDU 400 has a PCM TES 406 downstream of a heat exchanger 404. Referring to FIG. 4A, when the heat exchanger 404 in the CDU 400 can supply cool enough glycol to the PCM TES 406, the PCM stores this cool energy by changing from liquid to the solid phase. When handling spikes in computer rack output until the facility loop 101 can ramp up, the PCM TES 406 is sized to recharge in a few hours and to discharge in 5-10 minutes. In another embodiment, when the PCM TES 406 is operating to shave peak heat transfer from the facility loop 101, the PCM TES 406 may be sized to recharge in a longer timeframe (e.g., 4-12 hours) and to discharge over a few hours (e.g., 4-8 hours) during peak thermal load times.

In the example of FIG. 4A, where the PCM melts at 29° C., slightly lower fluid temperature (e.g., 27° C.) than the PCM melting temperature can be produced in the CDU 400 to re-charge the PCM TES 406. The PCM TES 406 includes a PCM inventory sensor 408 located within the PCM TES 406 that monitors the state of the PCM charge. The glycol flows inside an internal heat exchanger, such as tubes, of the PCM TES 406 while the PCM itself is outside of the internal heat exchanger. In this way, the glycol freezes and melts the PCM from inside the internal heat exchanger in the PCM TES 406 and there is no direct contact between the PCM and the glycol in the technical loop 103.

Because the CDU 400 is in the technical loop 103, the CDU 400 is close to the computer racks 402 which permits the CDU 400 to quickly cool the hot glycol mixture received from the computer racks 402 upon a sudden increase in computing power. The PCM melting temperature (e.g., 29° C.) is slightly lower than the required supply temperature to the computer racks 402 (e.g., 30° C.). When the sudden increase of computing activity of the computer racks 402 occurs, the chiller 106 in the facility loop 101 may not be able to catch up to satisfy the desired temperature going to the computer racks 402 during the first a few minutes (e.g., 5-10 minutes). That is when the PCM TES 406 of the CDU 400 can be used to provide the rapid response cooling needed. After that, when the chiller 106 has caught up, the CDU 400 can produce slightly colder fluid to recharge the PCM TES 406. In the example shown in FIG. 4B, when the PCM TES 406 is discharging, the chilled water of the facility loop is not cooling the glycol in the heat exchanger of CDU 400 as the glycol leaving the outlet of the racks is 40° C. and the glycol entering the inlet of the PCM TES 406 is also 40° C. This represents a condition where the load spike or surge happened while the chiller 106 of the facility loop 101 was off. For the 5-10 minutes it takes for the chiller 106 to ramp up, the charged PCM TES 406 will begin to discharge and deliver 30° C. glycol to the racks 402.

In another situation, the chiller 106 of the facility loop 101 may be running when the load spike from the computer racks 402 occurs and the heat exchanger 404 is receiving chilled water from the facility loop 101 but at a temperature and/or flow rate that is insufficient to completely resolve the load spike. In this situation, the PCM TES 406 receives partially cooled process fluid from the heat exchanger 404, such as 34° C., and the PCM TES 406 begins to melt and further cools the process fluid down to a temperature that is acceptable for the computer racks 402, such as 30° C. The PCM TES 406 receives the 34° C. process fluid for a period of time, such as 5-10 minutes, until the facility loop 101 begins providing sufficiently cool chilled water to the heat exchanger 404 to cool the entire cooling load from the computer racks 402.

The PCM is selected to charge and discharge to fit the temperature requirements needed to cool the computer racks 402 during the conditions. The CDU 400 lacks a chiller or a secondary heat exchanger. The PCM TES 406 can be standalone equipment added into the technical loop 103, or it can be a part of a packaged CDU 400 as shown in FIGS. 4A and 4B.

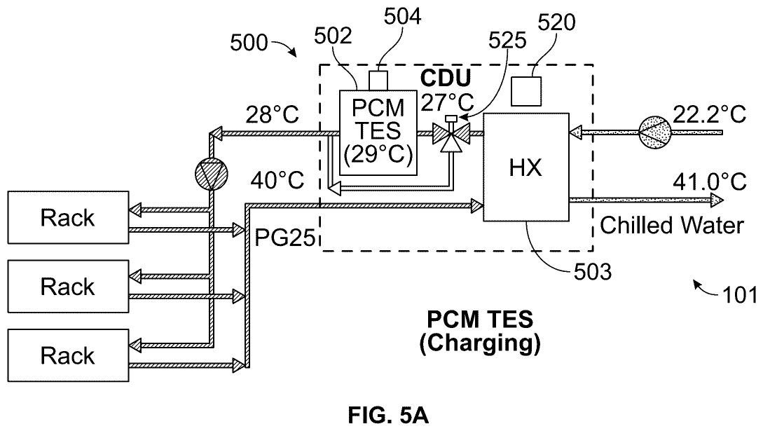

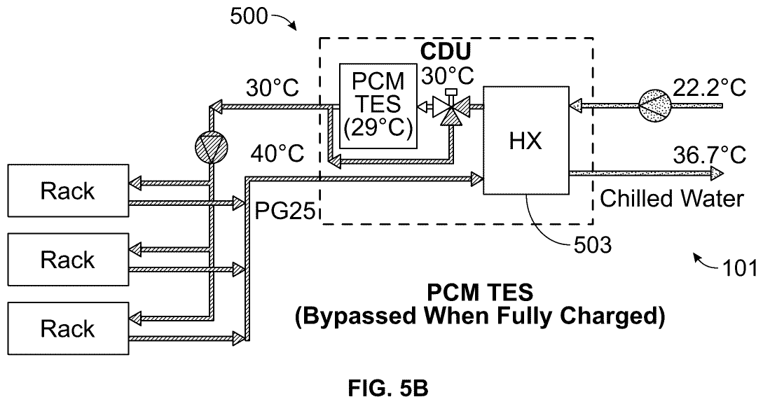

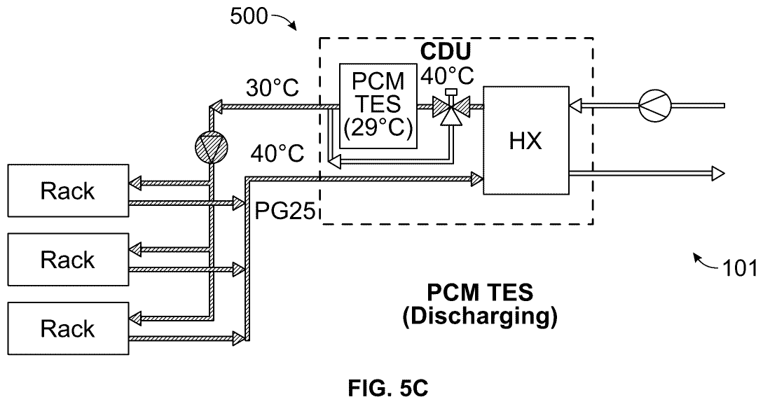

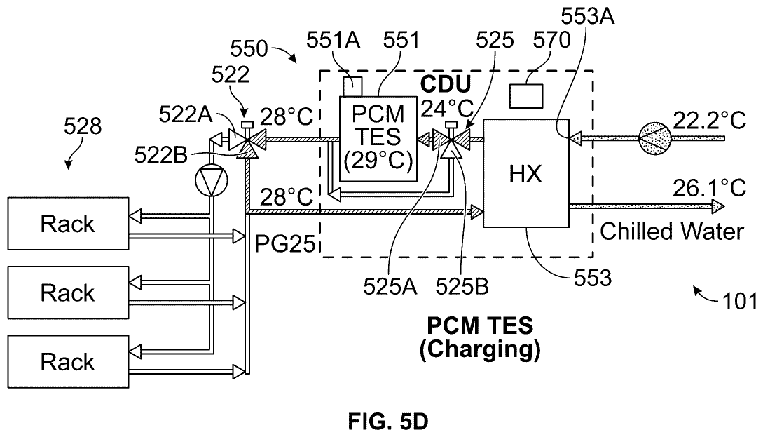

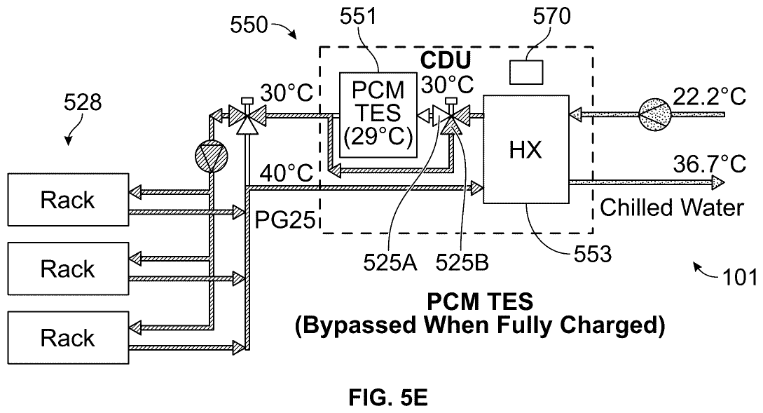

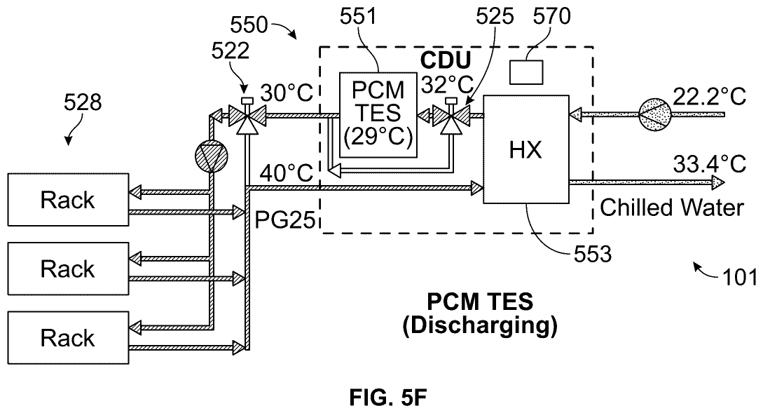

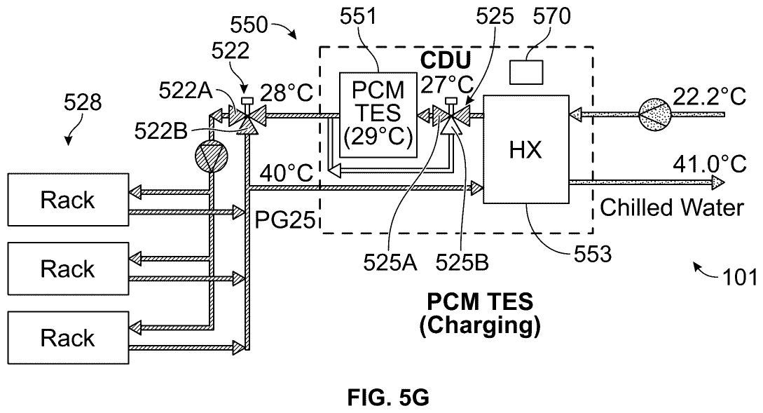

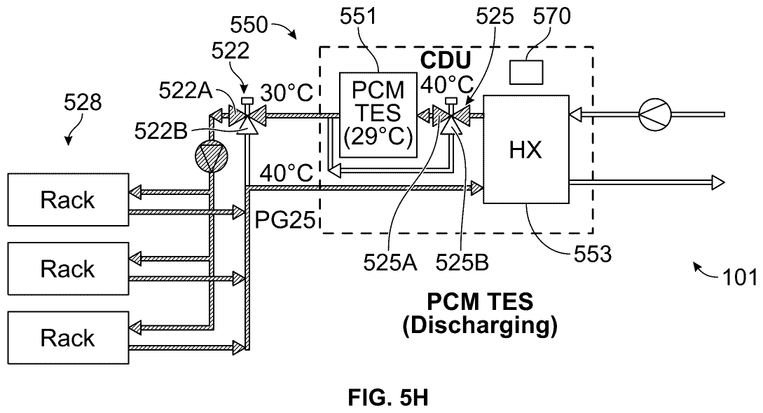

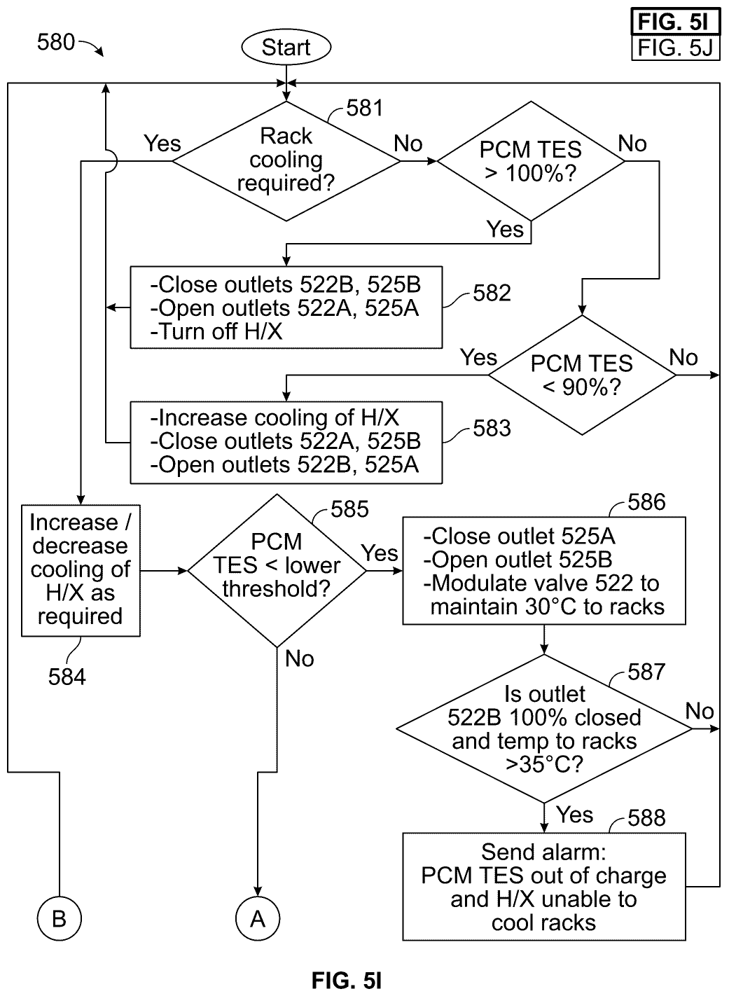

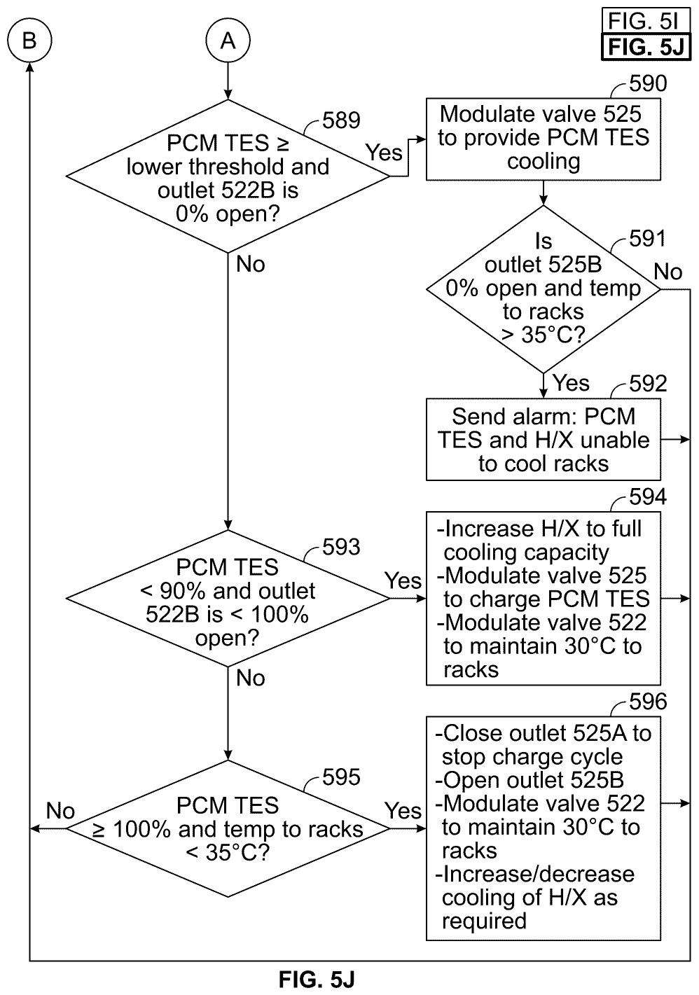

Regarding FIGS. 5A-5C, CDU 500 is similar to CDU 400 and has a PCM TES 502 downstream of a heat exchanger 503 in the technical loop 103. Like the other CDUs described herein, the CDU 500 may include a controller 520 configured to operate the CDU 500. The CDU 500 has a bypass valve 525 for the PCM TES 502 that permits the process fluid, such as a glycol mixture, of the technical loop 103 to bypass the PCM TES 502. The controller 520 communicates with an inventory sensor 504 of the PCM TES 502 to effect recharging of the PCM when needed by opening bypass valve 525 to allow glycol to flow through the PCM TES 502. Once the PCM TES 502 is fully charged, that bypass valve 525 directs glycol around the PCM TES 502 to avoid unnecessarily discharging the PCM and keeps the PCM TES 502 fully charged and available to cool when a spike heat load occurs. Bypassing the glycol around the PCM TES 502 also permits the temperature of chilled water provided by the facility loop 101 to be increased while maintaining 30° C. process fluid going to the computer racks 528. In one embodiment, the controller 520 is configured to switch the CDU 500 between a PCM TES charge mode, a PCM TES discharge mode, and a PCM TES bypass mode based at least in part upon data from PCM inventory sensor 504 and the cooling load required by the computer racks 102. In one approach, to preserve the charge of the PCM TES 502, the controller 520 may modulate the bypass valve 525 to control the flow through the PCM TES 502 to input only the amount of process fluid needed to maintain the mixed outlet temperature of 30° C. going to the computer racks 528.

Regarding FIGS. 5D-5F, CDU 550 is similar to CDU 500 and has a second bypass valve 522, such as a three-way valve, downstream of the rapid response cooling apparatus (e.g., PCM TES 551) in the technical loop 103 to modulate the flow of the process fluid (e.g., propylene glycol 25) to provide full, partial, or no flow of the process fluid of the technical loop 103 to the computer racks 528. The CDU 550 has a controller 570 configured to communicate with an inventory sensor 551A of the PCM TES 551 to effect recharging of the PCM TES 551 when needed by opening outlet 525A and closing outlet 525B of the first bypass valve 525. In another embodiment, the CDU 550 has a chiller instead of the PCM TES 551 to provide rapid cooling to the process fluid of the technical loop 103. An example of a CDU with a chiller instead of a PCM TES is shown in FIG. 2B.

Regarding FIG. 5D, the second bypass valve 522 has an outlet 522A that may be closed to limit or prevent flow of the process fluid to the computer racks 528 while the PCM TES 551 is recharging or may be opened to allow full or partial flow of the process fluid to the computer racks 528. The second bypass valve 522 has an outlet 522B that is opened when the outlet 522A is closed to direct the process fluid back toward a heat exchanger 553 of the CDU 550. Conversely, the outlet 522B is closed when the outlet 522A is opened to direct the process fluid to the computer racks 528. The controller 570 may modulate the process fluid through the valve 522 by partially opening the outlet 522B when mixing the process fluid returning from the computer rack 528 with process fluid from the PCM TES 551 (or from the heat exchanger 553 when the PCM TES 551 is bypassed) provides a desired temperature of process fluid returning to the heat exchanger 553. The heat exchanger 553 may be an indirect heat exchanger to transfer heat between the chilled water of the facility loop 101 or may be a chiller, as some examples.

Once the PCM TES 551 is fully charged, an outlet 525A of the first bypass valve 525 is closed and an outlet 525B of the first bypass valve 525 is opened to direct process fluid around the PCM TES 502 as shown in FIG. 5E. With the first bypass valve 525 in the bypass configuration of FIG. 5E, the PCM TES 551 is kept fully charged and available to provide rapid response cooling during a sudden surge in cooling load or demand or can also provide cooling during peak periods of time.

The CDU 550 has a controller 570 configured to switch the CDU 550 between a PCM TES charge mode (FIG. 5D), a PCM TES discharge mode (FIG. 5H), a PCM TES bypass mode (FIG. 5E), a PCM TES hybrid charge mode (FIG. 5G), and a PCM TES hybrid discharge mode (FIG. 5F) based at least in part upon data from PCM inventory sensor 504 and a surge in cooling load or demand of the computer racks 528.

The controller 570 may operate the CDU 550 in the PCM charge mode of FIG. 5D when cooling of the computer racks 528 is not needed and the PCM TES 551 state (e.g., charge level) is below a predetermined charge threshold. As part of the PCM charge mode, the controller 570 closes the outlet 522A of the first bypass valve 525 and opens to outlet 522B to allow all of the process fluid flow to the PCM TES 551. In the embodiment where the heat exchanger 553 is a chiller, the controller 570 ramps up operation of the chiller to cool the process fluid upstream of the PCM TES 551. The heat exchanger 553 transfers heat from the process fluid leaving the PCM TES 551 to chilled water of the facility loop 101 and directs cooled process fluid back to the PCM TES 551, which charges the PCM TES 551.

Once the PCM TES 551 has been fully charged, the controller 570 may close the outlets 522B, 525A and open the outlets 522A, 525B to bypass the process fluid from the heat exchanger 553 around the PCM TES 551 and direct the process fluid to the racks 528. This configuration keeps the PCM TES 551 charged and available to cool the computer racks 528 if there is a surge of a cooling load required by the computer racks 528 or during peak times.

The controller 570 may operate the CDU 550 in the PCM TES discharge mode of FIG. 5H when cooling is needed for the computer rack 528, the PCM TES 551 state (e.g., charge level) is above the predetermined charge threshold, and the facility loop 101 is unable to provide sufficiently cool water to an inlet 553A of the heat exchanger 553. As part of the PCM TES discharge mode, the controller 570 opens the outlets 522A, 525A and closes the outlets 522B, 525B to direct process fluid through the PCM TES 551, to the computer racks 528, and back to the heat exchanger 553.

In one situation, the facility loop 101 is providing chilled water to the heat exchanger 553 when the CDU 550 is in the PCM TES discharge mode of FIG. 5H, but the chilled water is at a temperature and/or flow rate that is insufficient to satisfy the surge in cooling load from the computer racks 528. The PCM TES 551 supplements the cooling provided by the heat exchanger 553 to reduce the temperature of the process fluid flowing to the computer racks 528 to an acceptable value.

In the PCM TES bypass mode of FIG. 5E, the controller 570 operates the first bypass valve 525 to bypass the flow of process fluid around the PCM TES 551 when the PCM TES 551 is fully charged and not needed to cool the computer racks 528. During the PCM bypass mode, when cooling of the computer racks 528 is needed and the PCM TES 551 is fully charged, the controller 570 implements logic to operate the heat exchanger 553 to cool the process fluid to the process fluid set temperature (e.g., 30° C.) and to modulate the second bypass valve 522 to maintain the process fluid at the process fluid set temperature (e.g., 30° C.).

The controller 570 may operate the CDU 550 in the PCM TES hybrid charge mode of FIG. 5G when cooling of the computer rack 528 is needed and the PCM TES 551 state (e.g., charge level) is below the predetermined charge threshold. In this situation, the chiller(s) in the facility loop 101 are running and the load in the computer racks 528 increases rapidly such that the rack outlet temperature spikes. The valve 525 will be modulated to melt the PCM of the PCM TES 551 to keep the temperature of the process fluid being directed to the computer racks 528 at the set point temperature (e.g., 30° C.).

The controller 570 opens valve outlets 522A, 525A, 522B and closes valve outlet 525B to direct the process fluid through the PCM TES 551 and to the computer racks 528. The opening of the valve outlet 522B permits the 40° C. process fluid from the computer racks 528 to travel into the outlet 522B of the valve 522 and enables the valve 522 to mix or modulate the 40° C. process fluid from the computer racks 528 with the 28° C. process fluid from the PCM TES 551 to provide 30° C. process fluid to the computer racks 528. The PCM TES hybrid charge mode of FIG. 5G allows simultaneous charging of the PCM TES 551 and providing cooled process fluid to the computer racks 528 at the set point temperature (e.g., 30° C.).

In an embodiment where the heat exchanger 553 is a chiller, the controller 570 ramps up operation of the chiller to sufficiently cool the process fluid to both charge the PCM TES 551 and provide the required cooling to the computer racks 528. In an embodiment where the heat exchanger 553 is an indirect heat exchanger, the controller 570 may operate the CDU 550 in the PCM TES hybrid charge mode of FIG. 5G when the computer racks 528 have a low cooling demand and the chilled water of the facility loop 101 provided to the heat exchanger 553 is able to sufficiently cool the process fluid to both charge the PCM TES 551 and provide the required cooling to the computer racks 528.

The controller 570 may operate the CDU 550 in the PCM hybrid discharge mode of FIG. 5F when computer rack 528 cooling is needed, the PCM TES 551 state (e.g., charge level) is above the predetermined charge threshold, and chilled water from the facility loop 101 is available to assist in cooling. The controller 570 is able to modulate the valve 522 to maintain the process fluid being supplied to the computer racks 528 at the process fluid set temperature (e.g., 30° C.). In one embodiment, the controller 570 is configured to transmit an alert to a remote device, such as a master controller of the facility or a user device such as a mobile phone, if the outlet 522B is closed (i.e., 0% open), the temperature of the process fluid provided to the computer racks 528 reaches an upper threshold temperature (e.g., 35° C.), the PCM TES 551 is out of charge or below a predetermined threshold (e.g., 10%), and the heat exchanger 553 is unable to sufficiently cool the computer racks 528.

Regarding FIGS. 5I and 5J, a method 580 is provided that may be utilized by the controller 570 to operate the CDU 550. The method 580 includes deciding whether the computer racks 528 require cooling at step 581, which may be determined using current draw or temperature sensors as discussed herein. If the computer racks 528 do not require cooling, the controller 570 operates the CDU 550 in a standby mode at step 582 or the PCM TES charge mode at step 583. For example, at step 582 the heat exchanger 553 is off, outlets 522B, 525B are closed, and outlets 522A, 525A are opened. With the outlets 522A, 525A open, the CDU 550 is in a standby mode with the PCM TES 551 available to provide cooling during a sudden surge in cooling load or demand.

If the computer racks 528 require cooling at step 581, the controller 570 increases or decreases the cooling provided by the heat exchanger at step 584 as required. For example, the step 584 may include ramping up the cooling provided by the heat exchanger 553 in an embodiment where the heat exchanger 553 is a chiller.

The controller 570 next evaluates whether the PCM TES 551 has a charge level below a lower charge level, such as less than 5%, at step 585. If so, the controller 570 operates the CDU 550 in the PCM TES bypass mode at step 586. If the controller 570 at step 587 determines the CDU 550 is unable to provide process fluid to the computer racks 528 below an upper threshold temperature (e.g., 35° C.), the controller 570 sends an alarm at step 588.

The controller 570 at step 589 determines whether the charge level of the PCM TES 551 is above the lower threshold at step 585 and whether the outlet 522B of the valve 522 is closed (e.g., 0% open). If so, the controller 570 at step 590 operates the CDU 550 in the PCM TES discharge mode or the PCM TES hybrid discharge mode, which includes the heat exchanger 553 cooling the process fluid, based upon the cooling demand of the computer racks 528. The step 590 includes the controller 570 modulating the valve 525 by adjusting the open percentage of the outlet 525A (e.g., increasing the open percentage) and the open percentage of the outlet 525B (e.g., decreasing the open percentage) to permit the PCM TES 551 to cool the process fluid. If the outlet 525B is 0% open and the process fluid temperature to the computer racks 528 exceeds the upper threshold temperature at step 591, the controller 570 sends an alarm at step 592.

The controller 570 determines at step 593 whether the PCM TES 551 has a charge below a predetermined standby level, such as 90%, and the outlet 522B is less than 100% open. If so, the controller 570 operates the CDU 550 in the PCM TES hybrid charge mode at step 594. Step 594 includes the controller 570 modulating the valve 525 to control the flow rate of process fluid to the PCM TES 551 to charge the PCM TES 551. The step 594 also includes modulating the valve 522 to control the flow rate of process fluid to the computer racks 528.

The controller 570 at step 595 determines whether the PCM TES 551 is above a maximum charge level (e.g., 100%) and whether the temperature of the process fluid to the computer racks 528 exceeds the upper threshold temperature at step 595. If so, the controller 570 operates the CDU 550 in the PCM TES bypass mode at step 596.

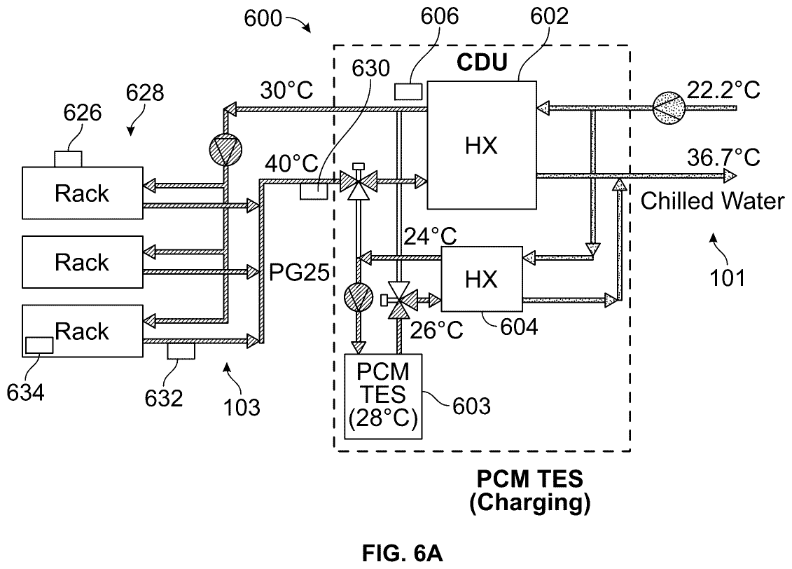

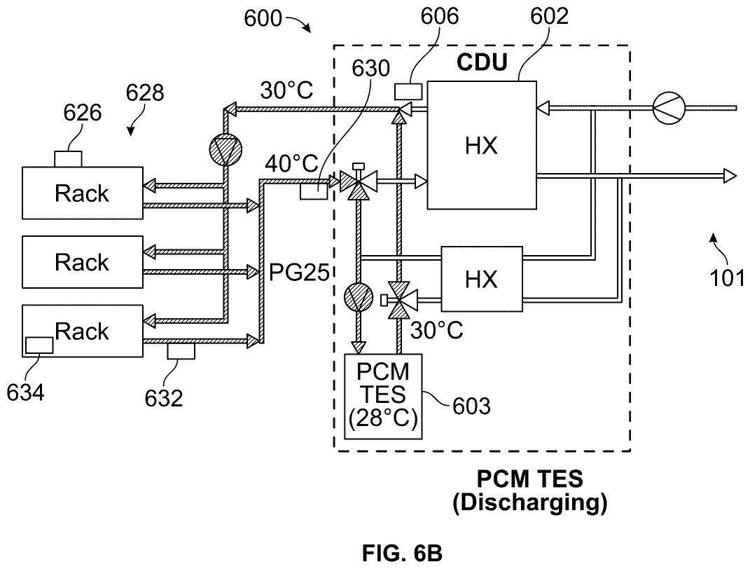

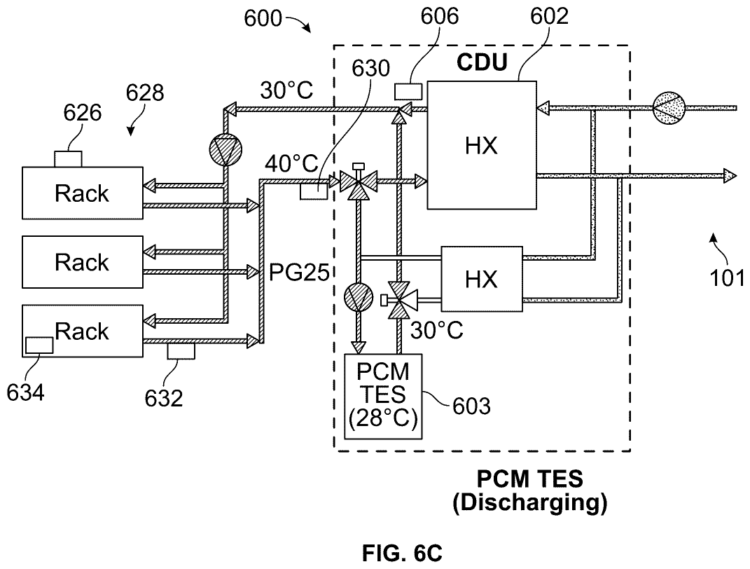

Regarding FIGS. 6A-6C, CDU 600 has a primary heat exchanger 602 to transfer heat between the fluids of the facility loop 101 and the technical loop 103. The CDU 600 has a PCM TES 603. The CDU 600 also includes a secondary heat exchanger 604 to transfer heat between the liquid (e.g., chilled water) of the facility loop 101 and the liquid (e.g., propylene glycol) of the technical loop 103. For the CDU 600, the PCM melting temperature (e.g., 24° C.-28° C.) is higher than the chilled water temperature in the facility loop (e.g., 22.2° C.) but lower than the required supply temperature to the computer racks 102 (e.g., 30° C.). The primary heat exchanger 602 is used to produce the required 30° C. process fluid to the computer racks 628, while a secondary heat exchanger 604 is used to produce colder fluid temperature (e.g., 24° C.) to re-charge the PCM TES 603. This provides more flexibility in the selection of the PCM itself and gives more precise control to provide immediate cooling from the PCM TES 603 when required. The CDU 600 lacks a chiller. The CDU 600 has a controller 606 configured to switch the CDU 600 between PCM TES charge and discharge modes based at least in part upon data from a PCM inventor sensor and the cooling load required by the computer racks 628. The PCM TES 603 of the CDU 600 can be standalone equipment added to the technical loop 103 together with the secondary heat exchanger 602 and a pump, or the PCM TES 603 can be a part of a packaged CDU. The packaged CDU 600 may have two heat exchangers to produce two different fluid temperatures (one for cooling computer racks 628, the other for PCM TES 603 recharging).

In one embodiment, the controller 606 is connected to one or more power draw sensors 626 of computer racks 628. The controller 606 receives data from the power draw sensors 626 that a power spike is occurring which will engage the rapid response to the PCM TES 603 by immediately flowing the process fluid (e.g., glycol) through the PCM TES 603 to reduce the time it takes for the CDU 600 to begin discharging the PCM TES 603. As with many thermal systems, there is a lag time between when the heat load from the computer racks 628 increases and when the temperature of the glycol returning from the computer racks 628 increases enough for a glycol temperature sensor 630 of the CDU 600 to detect the increase in temperature and cause the controller 606 to allow the glycol to flow into the PCM TES 603 and begin the discharging process. Controller 606 implements the logic that when power draw sensor 626 remains above a preset value for a predetermined time period (e.g., 5 seconds) that the power spike is real and to begin the discharging PCM TES 603 process faster than waiting for temperature sensors to detect a corresponding increase in glycol temperature. The controller 606 may be in communication with other sensors to detect a load increase in the computer racks 628, such as one or more temperature sensors 632 at one or more glycol outlets of the computer racks 628 and/or one or more temperature sensors 634 at one or more electronic components of the computer racks 628. In this manner, the controller 606 is in communication with multiple sensors that enable a rapid detection of a spike in computer electrical power consumption and/or glycol temperature and a corresponding response by the controller 606 of discharging the PCM TES 603 until the chiller of the facility loop can catch up.

FIG. 6B shows the PCM TES 603 discharging while the facility loop 101 is just starting up and there is no chilled water flow to the heat exchanger 602. Another situation is when the facility loop 101 is running and providing chilled water to the heat exchanger 602, but the cooling demand from the computer racks 628 increases rapidly such that the rack outlet temperature spikes and the temperature of the process fluid recirculated to the computer racks 628 exceeds the temperature set point (30° C.). During this time, the controller 606 discharges the PCM TES 603 as shown in FIG. 6C to provide additional cooling while the facility loop 101 ramps up to meet the increased cooling load from the computer racks 628.

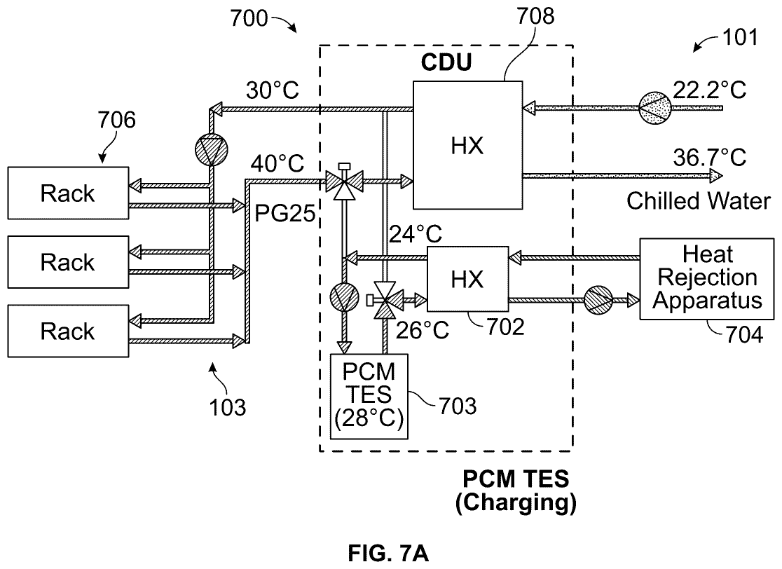

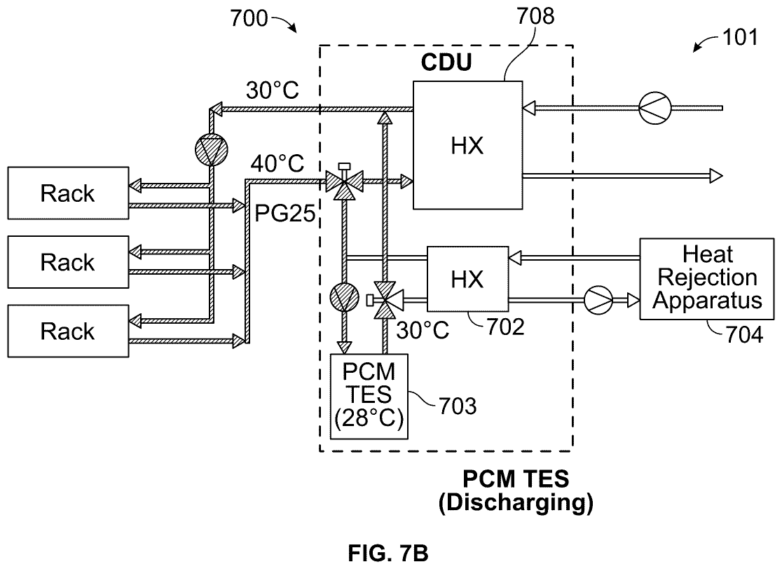

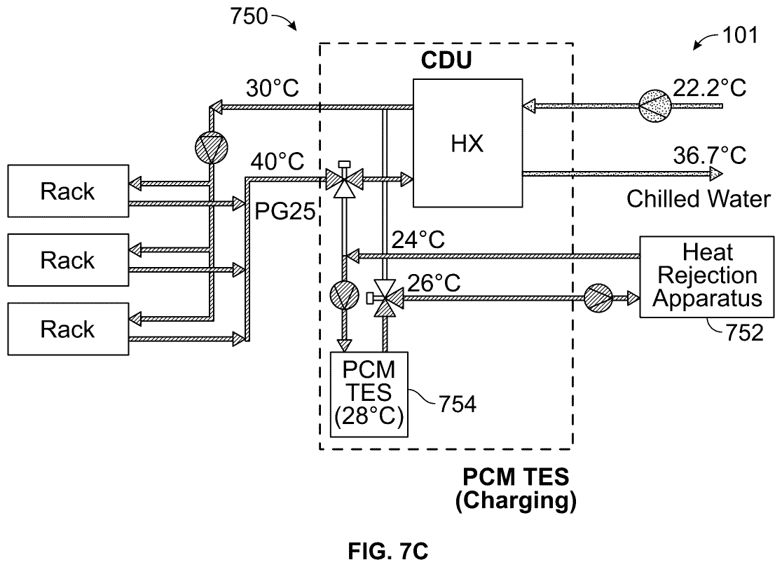

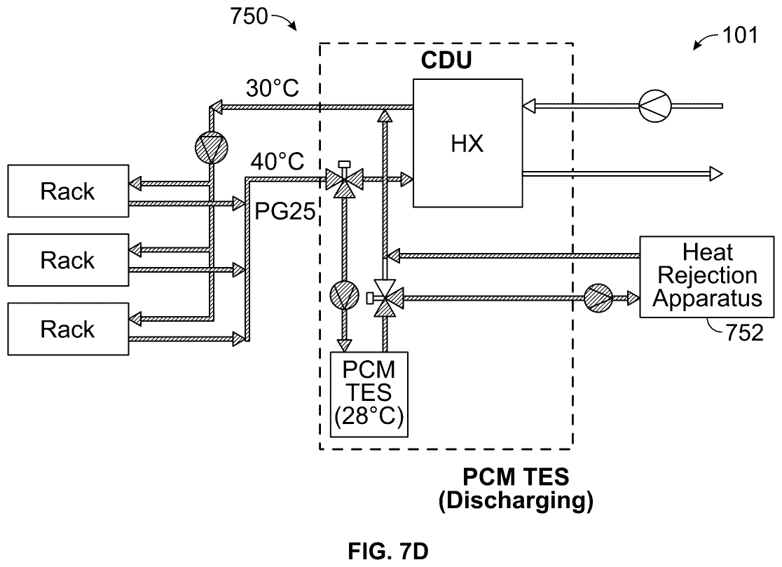

Regarding FIGS. 7A-7B, CDU 700 has a secondary heat exchanger 702 to facilitate charging of a PCM TES 703 and a dedicated heat rejection apparatus 704 for cooling the process fluid of the technical loop 103 that charges the PCM TES. In some cases, such as in colder climates or during winer months, heat exchanger 702 may be bypassed or eliminated and the PCM TES 703 can be charged directly by the dedicated heat rejection apparatus 704. As shown in FIG. 7A, using dedicated heat rejection apparatus 704 ensures the PCM TES 703 is independently charged regardless of the condition of the chilled water of the facility loop and, in addition, can supply colder temperatures to the PCM TES 703 for faster charging and to allow a wider range of PCM. In FIG. 7B, when the CDU 700 discharges the PCM TES 703, the dedicated heat rejection apparatus 704 is off and the flow of glycol is diverted from the rack heat load through the PCM TES 703 and back to the inlets of the computer racks 706 to ensure the fluid is cold enough during the spike period. FIG. 7B shows the PCM TES 703 discharging when the facility loop 101 is just starting up. In another situation, the facility loop 101 is running and providing chilled water to the heat exchanger 708. However, the temperature and/or flow rate of the chilled water is insufficient and the PCM TES 703 is discharged to supplement the cooling provided by the heat exchanger 708.

If there is an extended period of time that the PCM TES 703 provides cooling and runs out of PCM inventory, the dedicated heat exchange apparatus 704 can be turned back on (see FIG. 7D) to supply cooling until the chilled water of the facility loop reaches a sufficiently low temperature to cool the glycol at a primary heat exchanger 708 of the CDU 700. The CDU 700 allows redundant cooling to the PCM TES 703 for charging and also provides backup cooling during more extended periods of down time (e.g. >10 minutes) of the facility loop.

Regarding FIG. 7C, CDU 750 has a heat rejection apparatus 752 that is operable to charge a PCM TES 754 directly without a secondary heat exchanger. In this embodiment, the same working fluid will be used in the technical loop 103 and between the heat rejection apparatus 752 and the PCM TES 754.

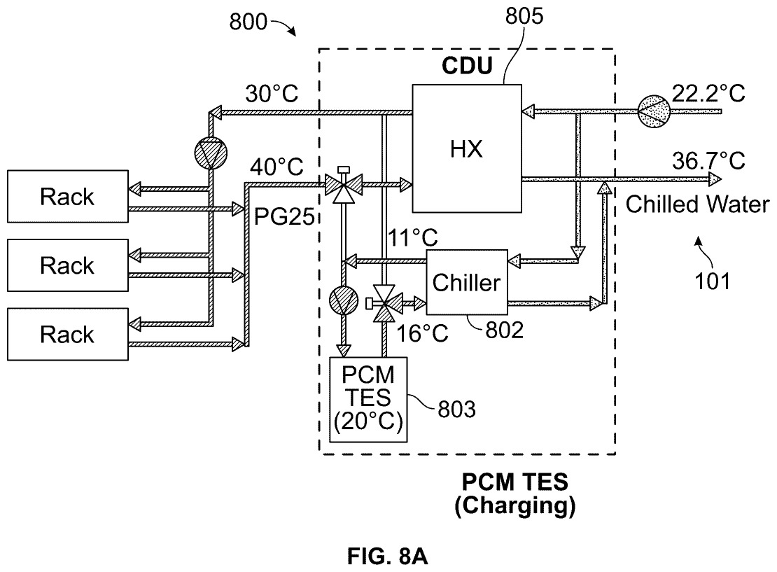

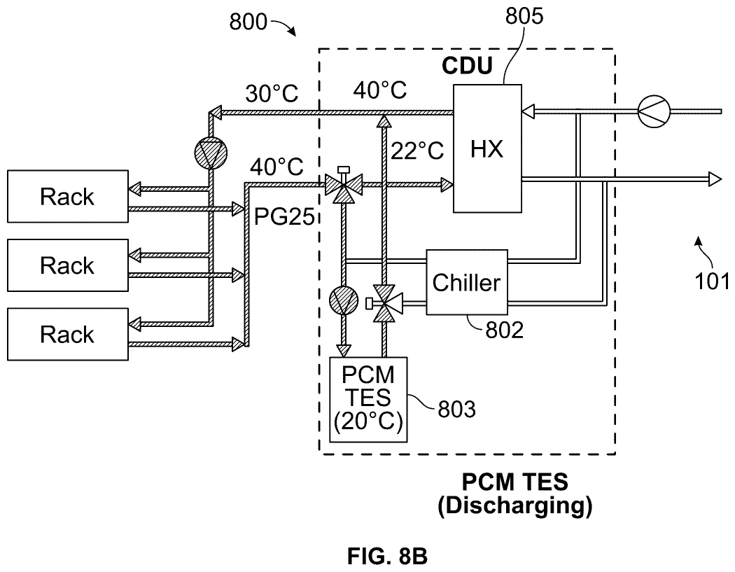

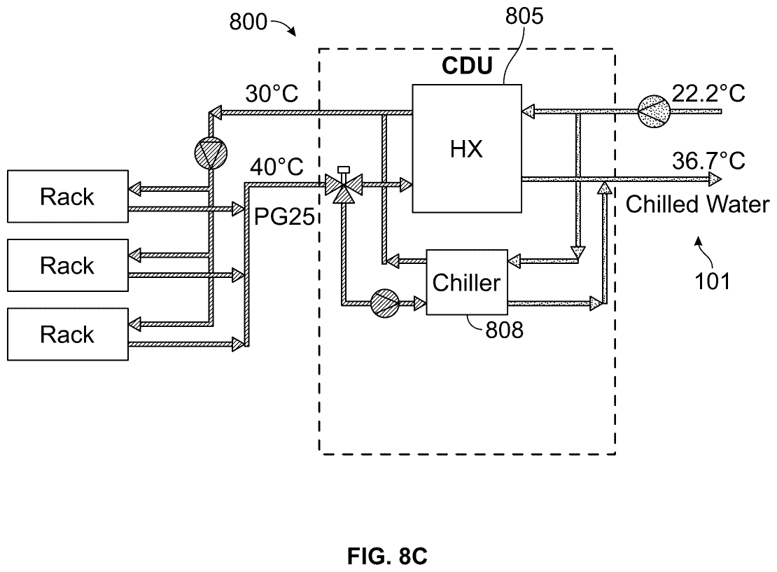

With reference to FIGS. 8A-8B, CDU 800 has a chiller 802 to recharge the PCM TES 803. The chilled water from the facility loop 101 is used to reject heat from the chiller 802. The PCM melting temperature (e.g., <24° C.) is close to or lower than the chilled water temperature in the facility loop 101 (e.g., 22.2° C.), so the chiller 802 is needed to recharge the PCM TES. If the PCM TES 803 is out of charge, the chiller 802 may be used to provide additional cooling to the heat exchanger 805.

Regarding FIG. 8C, the CDU 800 may be provided with a boost chiller 808 instead of the PCM TES 803 to provide additional cooling to the heat exchanger 805 during cooling load surge periods to maintain a mixed temperature of 30° C. to the computer racks.

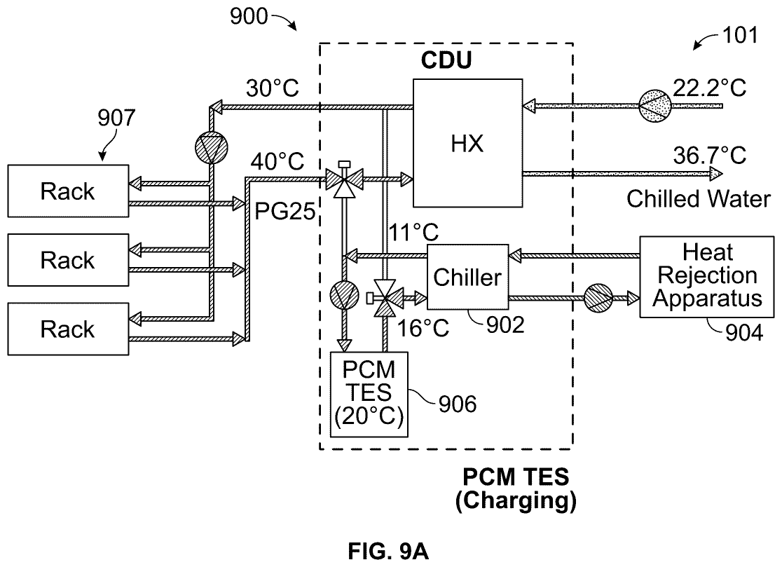

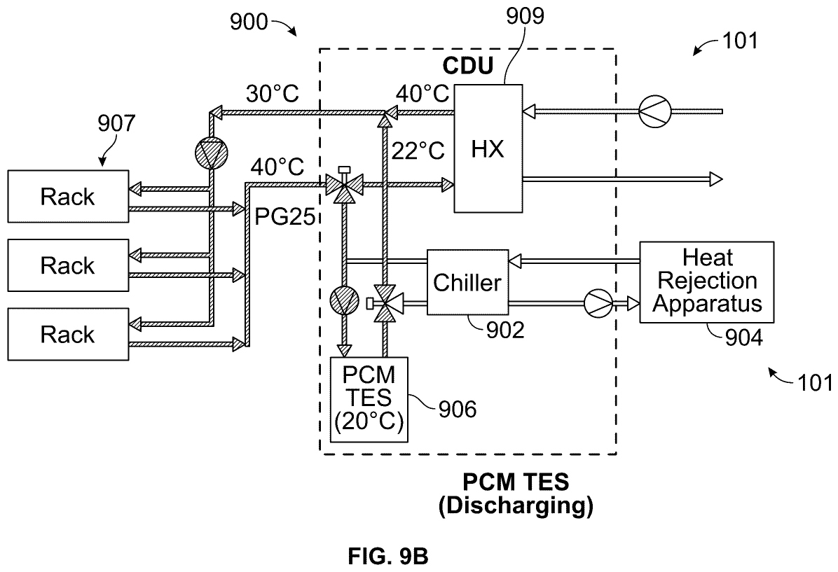

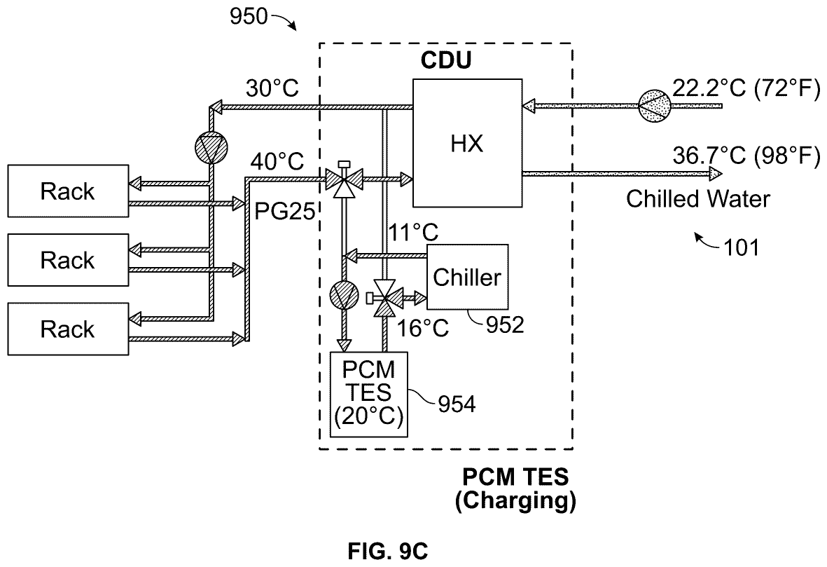

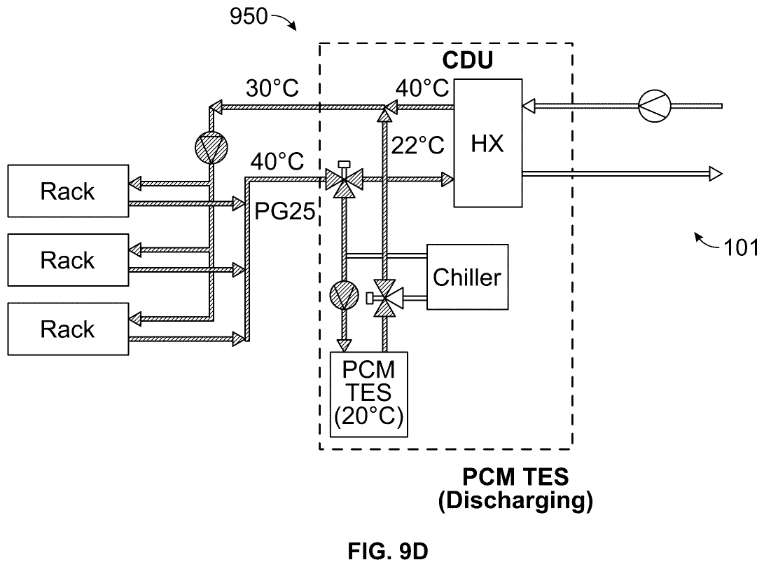

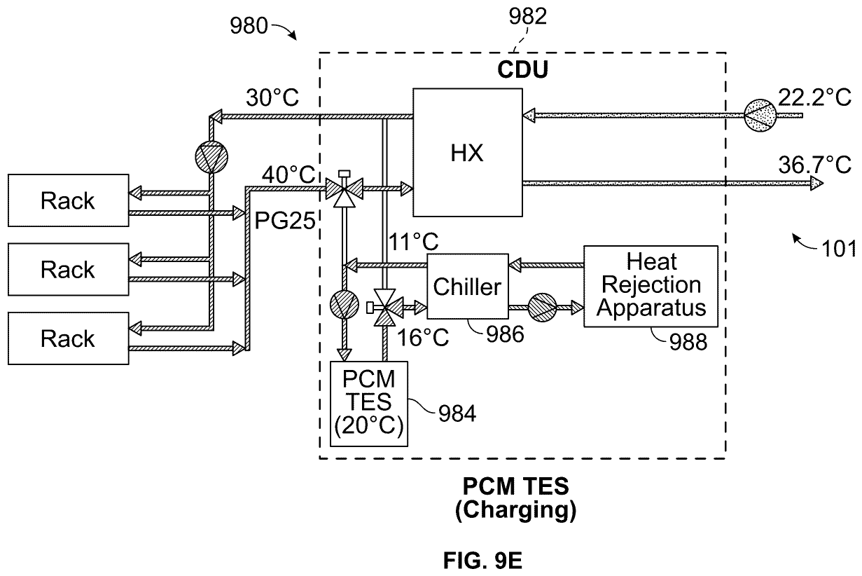

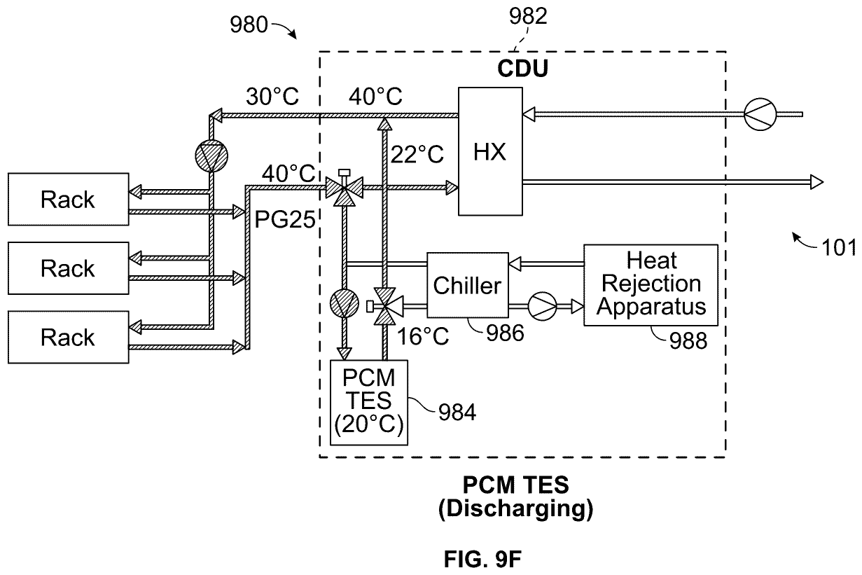

Regarding FIGS. 9A-9B, CDU 900 has a chiller 902 to recharge the PCM TES 906. The chiller 902 has a dedicated heat rejection apparatus 904. The heat rejection apparatus 904 is independent of the facility loop 101 such that no extra cooling capacity is required from the central chiller plant, e.g., chiller 106, of the facility loop 101 to charge the PCM TES 906. Under certain outdoor temperature conditions, the chiller 902 can be shut off and the process fluid of the heat rejection apparatus 904 can bypass the chiller 902 and be used directly to recharge the PCM TES 906. The dedicated heat rejection apparatus 904 enables the CDU 900 to ensure the PCM TES 906 is independently charged regardless of the condition of the facility loop and, in addition, can supply colder temperatures to the PCM TES 906 for faster charging and to allow a wider range of phase change materials to be used in the PCM TES 906. In another embodiment, the PCM TES 906 is omitted and the chiller 902 is operated as a boost chiller to provide cooling for surges in heat generated by the computer racks.

Regarding FIG. 9B, when the PCM TES discharging mode is implemented, the heat rejection apparatus 904 and the chiller 902 are off and the glycol flow is directed from the computer racks 907 through the PCM TES 906 and back to the process fluid inlets of the computer racks 907 to ensure the glycol is cold enough during the spike period. In some instances, the heat exchanger 909 will initially provide some cooling and the PCM TES 906 assists the heat exchanger 909 in providing cooling to the computer racks 907 as the heat exchanger 909 provides increasing cooling as the chiller(s) of the facility loop 101 ramps up. If there is an extended period of time that the PCM TES 906 needs to provide cooling and runs out of PCM inventory, the heat exchange apparatus 904 and chiller 902 can be turned back on to supply cooling until the facility loop is operational to provide the cooling required by the computer racks 907. The heat rejection apparatus 904 thereby provides redundant cooling to the PCM TES 906 for charging and also provides backup cooling during more extended periods of down time (e.g. >10 minutes) of the facility loop 101.

Regarding FIGS. 9C and 9D, CDU 950 is similar to CDU 900 and has a dedicated chiller 952 for charging a PCM TES 954 of the CDU 950. The chiller 952 is an air-cooled chiller. The CDU 950 may thereby operate the chiller 952 to charge the PCM TES 954 without cooling from the facility loop or dedicated heat rejection equipment. The air-cooled chiller 952 can be an integrated system, or it can also be a split system with evaporator, compressor, and expansion valve inside the CDU 900 while the condenser is external to the CDU 950. The chiller 952 allows redundant cooling to the PCM TES 954 for charging and also provides backup cooling during more extended periods of down time (e.g. >10 minutes) of the facility loop.

With reference to FIGS. 9E and 9F, CDU 980 has an outer structure such as a housing 982 and a PCM TES 984, chiller 986, and heat rejection apparatus 988 in the housing 982. In this manner, the dedicated heat rejection apparatus 988 is packaged with the PCM TES 984 and chiller 986 of the CDU 980. The CDU 980 allows redundant cooling to the PCM TES 984 for charging and also provides backup cooling during more extended periods of down time (e.g. >10 minutes) of the facility loop.

Under certain outdoor temperature conditions, the chiller 986 can be run in an economizer mode, shutting off the chiller 986 itself, with the heat rejection apparatus 988 producing the cold fluid temperatures required for higher temperature PCM materials. This may require an additional heat exchanger in some cases. The associated heat rejection apparatus 988 would be sized for the most difficult duty whether the economization or the chiller heat rejection duty. Some air cooled chillers also have an economizer coil which may be utilized in some embodiments.

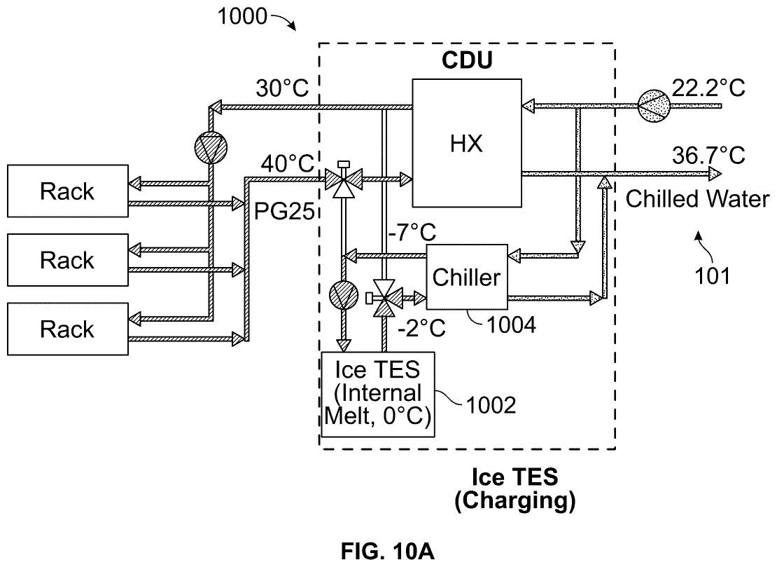

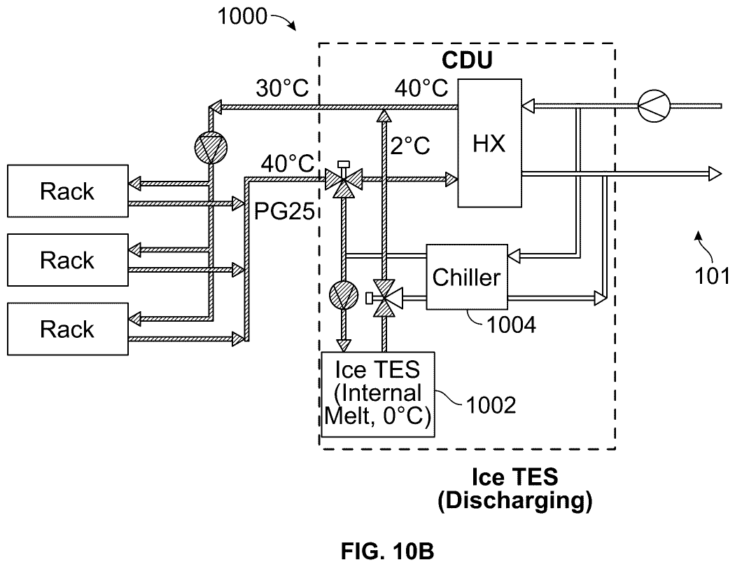

Turning to FIGS. 10A-10B, CDU 1000 has an internal build/melt ice TES 1002 and a chiller 1004. The chilled water of the facility loop 101 is used to reject heat from the chiller 1004 during the ice build mode. The internal-melt ice TES 1002 includes a tank containing water and coil tubes or plates submerged in the water. The propylene glycol 25 (PG25) of the technical loop 103 travels in the interior of the coil tubes or plates and ice is formed on the exterior of the coil tubes as the water in the tank turns to ice. During the charging mode, the chiller 1004 is used to cool the PG25 to a subzero temperature (e.g., −7° C.). In one embodiment, a dedicated heat rejection apparatus (e.g., a fluid cooler or cooling tower) may be included to reject heat from the chiller 1004 rather than utilizing the chilled water of the facility loop 101 to reject heat from the chiller 1004.

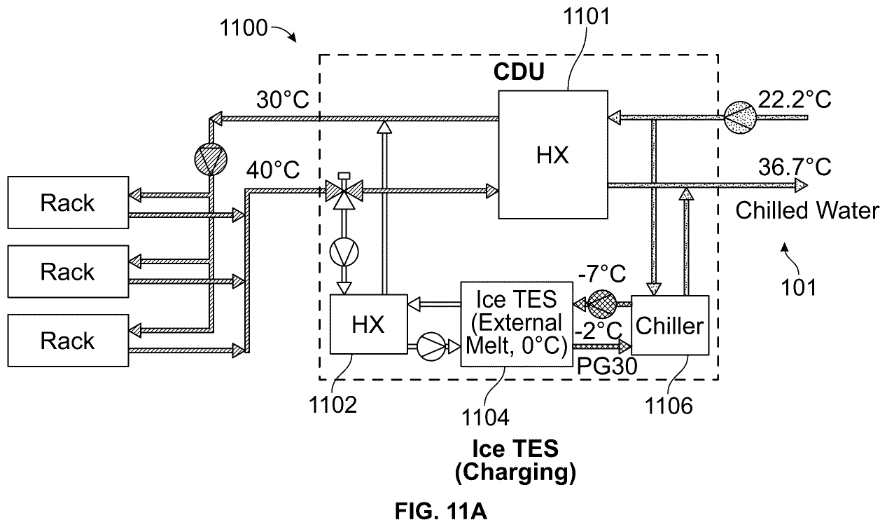

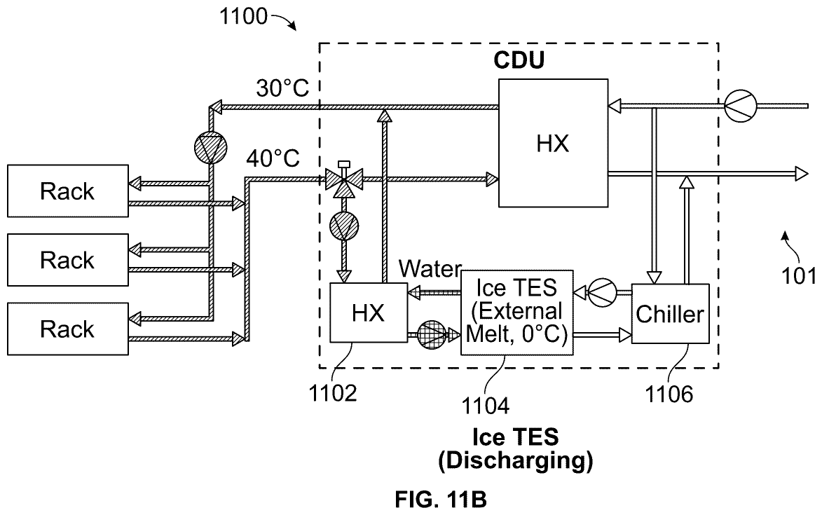

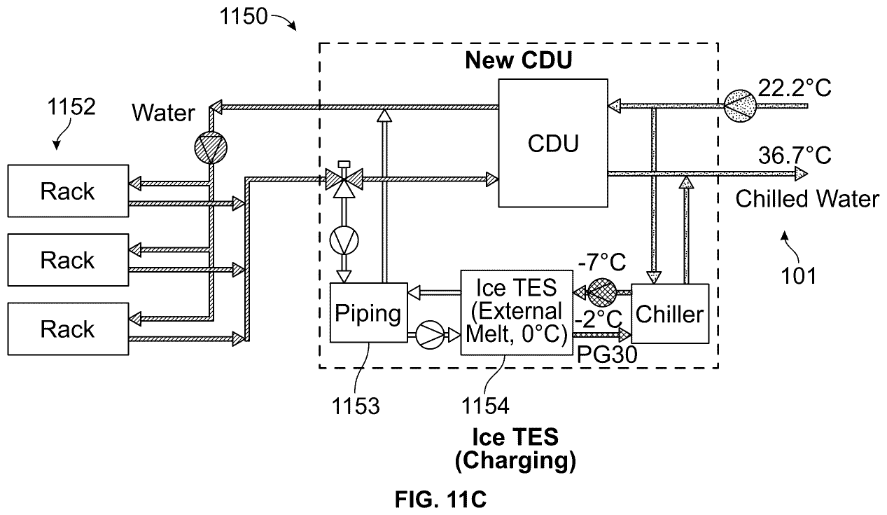

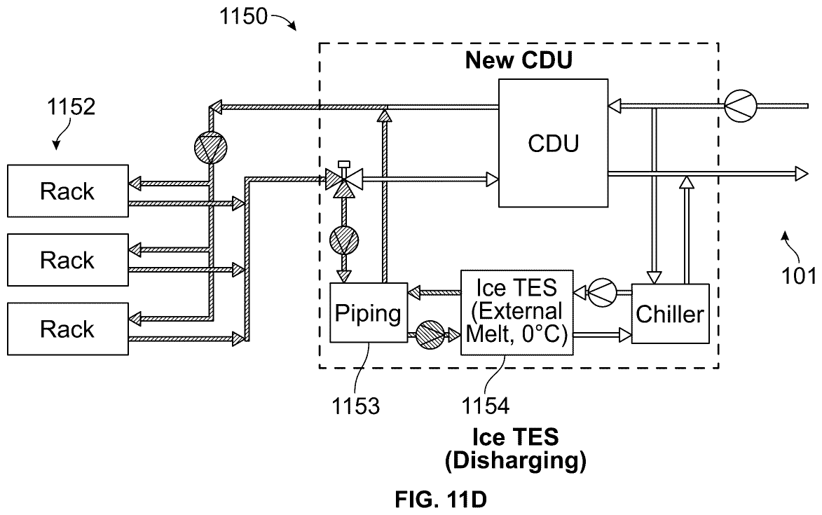

Regarding FIGS. 11A-11B, CDU 1100 has a primary heat exchanger 1101, a secondary heat exchanger 1102, an external-melt ice TES 1104, and a chiller 1106. The chiller 1106 is operable to charge the external-melt ice TES 1104 and chilled water of the facility loop absorbs heat from the chiller 1106 during the ice build mode. One advantage of using an external melt ice TES 1104 is its ability to provide immediate cooling when a spike in heat load occurs and the external melt ice TES 1104 also provides nearly constant output temperature throughout most of the melt cycle regardless of the magnitude of the heat load spike. The secondary heat exchanger 1102 decouples water utilized in the external-melt ice TES 1104 from the process fluid (e.g., a glycol-based fluid such as propylene glycol 25) of the technical loop 103. In another approach, the secondary heat exchanger 1102 may be integrated into the ice TES 1104, such as a finned coil in an external melt ice tank where the PG 25 glycol is pumped through the finned coil which is immersed in the water of the ICE TES tank.

The external-melt ice TES 1104 has coil tubes or plates that receive a cooled glycol-based fluid such as propylene glycol 30 (PG30) from the chiller 1006. The external-melt ice TES 1104 includes water contacting exteriors of the coil ice tubes that freeze during the recharge mode of the CDU 1100. In another embodiment, an air pump is used to promote heat transfer between the water and ice on the tubes instead of a still tank of water. The chiller 1106 is used to cool the PG30 to a subzero temperature (e.g., −7° C.) during the ice build or recharging mode. In one embodiment, a dedicated heat rejection apparatus, such as a fluid cooler or cooling tower, can be used to reject heat from the chiller 1106 instead of the chilled water of the facility loop 101.

Regarding FIG. 11C, CDU 1150 utilizes water in the technical loop that includes computer racks 1152. The CDU 1150 has piping 1153 instead of the secondary heat exchanger 1102 so that water used to cool the computer racks 1152 is in communication with the external melt ice TES 1154. Because water is utilized in the technical loop and is cooled by the ice TES 1154, CDU 1150 can operate without a secondary heat exchanger like the heat exchanger 1102. The computer racks 1152 associated with the CDU 1150 may each have heat exchangers so that the process fluid water is kept from reaching the computers of the computer racks 1152. Regarding FIG. 11D, the ice TES 1154 may be discharged to provide cooling to the computer racks 1152.

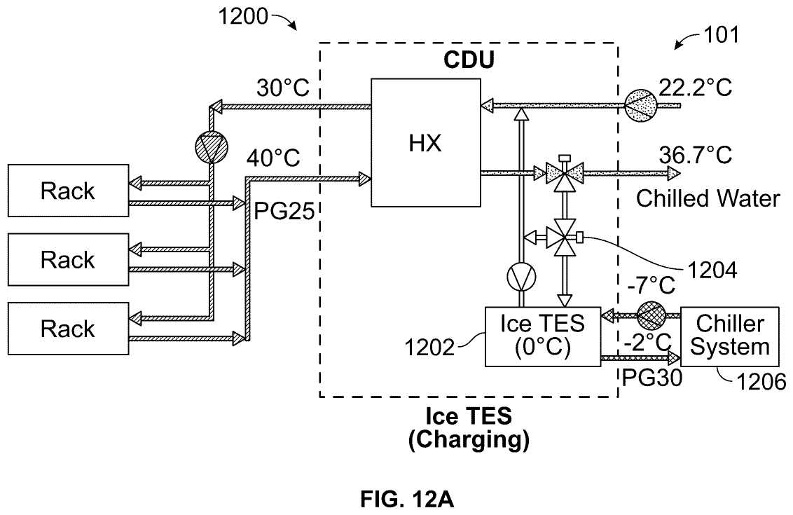

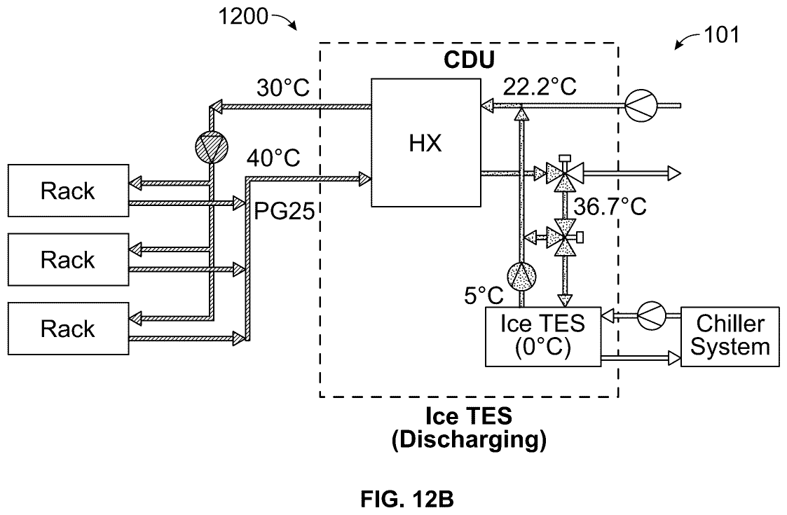

FIGS. 12A-12B disclose a CDU 1200 having an ice TES 1202, such as an external-melt ice TES, of the associated facility loop. CDU 1200 has a three-way valve 1204 that modulates fluid flow to meet the required supply temperature. Since the working fluid is water in the facility loop, external melt ice TES can be used without a heat exchanger of the CDU 1200. The ice TES 1202 is operatively connected to a chiller system 1206 that may reject heat to the process fluid of the facility loop. The ice TES 1202 may be charged independently of the facility loop 101. In another embodiment, the chiller system 1206 may have a dedicated heat rejection apparatus to reject heat from the chiller system 1206.

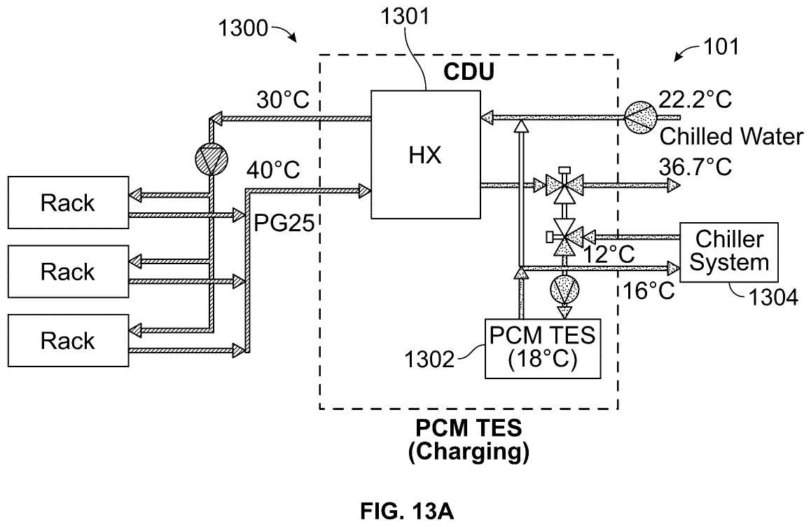

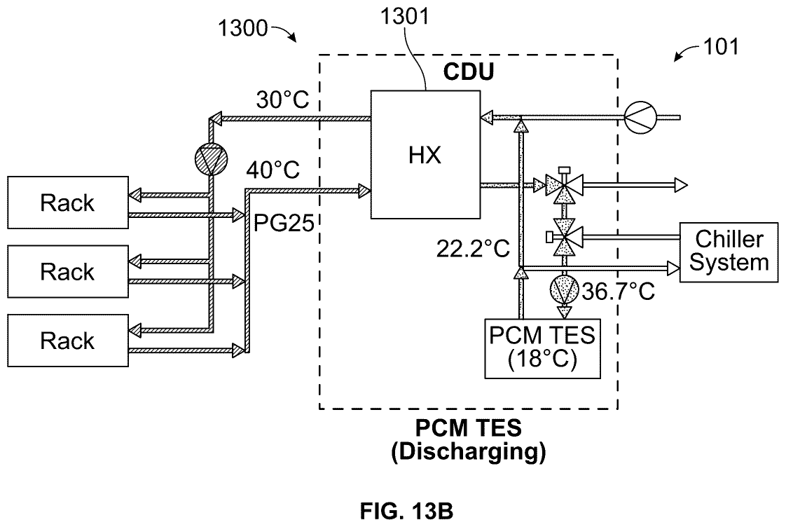

Regarding FIGS. 13A-13B, CDU 1300 has a PCM TES 1302 of the associated facility loop. The PCM melting temperature (e.g. 18° C.) is below the required chilled water temperature (e.g., 22.2° C.) for heat exchanger 1301. The PCM TES 1302 is operatively connected to a chiller system 1304 that may reject heat to the process fluid of the facility loop. In another embodiment, the chiller system 1304 may have a dedicated heat rejection apparatus to reject heat from the chiller system 1304. In some instances, the PCM TES of the CDU 1300 will be discharging to supplement cooling provided from facility loop 101 until the facility loop 101 is able to provide sufficiently cool water to the heat exchanger 1301 of the CDU 1300.

Uses of singular terms such as “a,” “an,” are intended to cover both the singular and the plural, unless otherwise indicated herein or clearly contradicted by context. The terms “comprising,” “having,” “including,” and “containing” are to be construed as open-ended terms. It is intended that the phrase “at least one of’ as used herein be interpreted in the disjunctive sense. For example, the phrase “at least one of A and B” is intended to encompass A, B, or both A and B.

While there have been illustrated and described particular embodiments of the present invention, it will be appreciated that numerous changes and modifications will occur to those skilled in the art, and it is intended for the present invention to cover all those changes and modifications which fall within the scope of the appended claims. For example, the facility loop may include an air cooled chiller, a heat rejection device like a cooling tower only, lake cooling, or other cooling approaches. Further, it will be appreciated that the TES device can work in conjunction with chilled water from the facility loop to provide cooling as the chiller of the facility loop restarts or ramps up to satisfy a spike in cooling capacity. As yet another modification, a water-based sensible storage may be utilized with one or more of the CDUs discussed above.

What is claimed is:

1. A coolant distribution unit for cooling a process fluid of a technical loop including computers, the coolant distribution unit comprising:
a heat exchanger configured to transfer heat from the technical loop process fluid to a process fluid of a facility loop;
a rapid response cooling apparatus operatively connected to the heat exchanger; and
a controller configured to:
determine a surge of a cooling load of the computers based at least in part upon data from a sensor of the technical loop; and
cause the rapid response cooling apparatus to contribute to satisfying the cooling load of the computers based at least in part upon the surge of the cooling load of the computers.

2. The coolant distribution unit of claim 1 wherein the controller is configured to determine the surge of the cooling load of the computers based at least in part upon the cooling load exceeding a threshold cooling load for a predetermined time period.

3. The coolant distribution unit of claim 1 further comprising the sensor, the sensor configured to detect a parameter indicative of the cooling load of the computers.

4. The coolant distribution unit of claim 3 wherein the parameter is an electrical consumption parameter.

5. The coolant distribution unit of claim 3 wherein the parameter is a temperature of the technical loop process fluid.

6. The coolant distribution unit of claim 1 wherein the rapid response cooling apparatus includes a thermal energy storage configured to receive the technical loop process fluid;
wherein the coolant distribution unit has a thermal energy storage discharge mode wherein the thermal energy storage cools the technical loop process fluid; and
wherein the controller is configured to cause the coolant distribution unit to be in the thermal energy storage discharge mode based at least in part upon the surge in the cooling load of the computers.

7. The coolant distribution unit of claim 1 wherein the rapid response cooling apparatus includes a thermal energy storage configured to receive the facility loop process fluid;
wherein the coolant distribution unit has a thermal energy storage discharge mode wherein the thermal energy storage cools the facility loop process fluid; and
wherein the controller is configured to cause the coolant distribution unit to be in the thermal energy storage discharge mode based at least in part upon the surge in the cooling load of the computers.

8. The coolant distribution unit of claim 1 wherein the rapid response cooling apparatus includes a thermal energy storage;
wherein the coolant distribution unit has a thermal energy storage bypass mode wherein the thermal energy storage has a reduced contribution to satisfying the cooling load of the computers; and
wherein the controller is configured to cause the coolant distribution unit to be in the thermal energy storage bypass mode based at least in part upon an absence of the surge in cooling load of the computers.

9. The coolant distribution unit of claim 1 wherein the rapid response cooling apparatus includes a thermal energy storage;
wherein the coolant distribution unit has a thermal energy storage charging mode wherein the thermal energy storage is charged by either the technical loop process fluid or the facility loop process fluid; and
wherein the controller is configured to cause the coolant distribution unit to be in the thermal energy storage charging mode based at least in part upon a low cooling load of the computers.

10. The coolant distribution unit of claim 1 wherein the rapid response cooling apparatus includes a thermal energy storage;
wherein the coolant distribution unit has a thermal energy storage charging mode wherein the thermal energy storage is charged by either the technical loop process fluid or the facility loop process fluid; and
wherein the controller is configured to cause the coolant distribution unit to be in the thermal energy storage charging mode based at least in part upon the facility loop being able to satisfy the cooling load of the computers.

11. The coolant distribution unit of claim 1 wherein the rapid response cooling apparatus includes a thermal energy storage;
wherein the heat exchanger comprises a chiller; and
wherein the coolant distribution unit has a thermal energy storage hybrid discharge mode wherein the chiller and the thermal energy storage contribute to satisfying the cooling load of the computers.

12. The coolant distribution unit of claim 1 wherein the rapid response cooling apparatus includes a thermal energy storage;
wherein the heat exchanger comprises a chiller;
wherein the coolant distribution unit has a thermal energy storage hybrid charging mode wherein the chiller satisfies the cooling load of the computers and charges the thermal energy storage.

13. The coolant distribution unit of claim 1 wherein the rapid response cooling apparatus includes a thermal energy storage; and
wherein the controller is configured to cause the thermal energy storage to contribute to cooling of the technical loop process fluid based at least in part upon the surge in cooling load of the computers and a charge level of the thermal energy storage.

14. The coolant distribution unit of claim 1 wherein the rapid response cooling apparatus includes a thermal energy storage;
a secondary heat exchanger configured to transfer heat between the facility loop process fluid and a process fluid for charging the thermal energy storage;
wherein the coolant distribution unit has a thermal energy storage charging mode wherein the thermal energy storage is charged by the process fluid of the secondary heat exchanger; and
wherein the controller is configured to cause the coolant distribution unit to be in the thermal energy storage charging mode based at least in part upon a low cooling load of the computers.

15. The coolant distribution unit of claim 1 wherein the rapid response cooling apparatus includes a thermal energy storage;
a heat rejection apparatus operatively connected to the thermal energy storage;
wherein the coolant distribution unit has a thermal energy storage charging mode wherein the heat rejection apparatus facilitates charging of the thermal energy storage; and
wherein the controller is configured to cause the coolant distribution unit to be in the thermal energy storage charging mode based at least in part upon a low cooling load of the computers.

16. The coolant distribution unit of claim 15 further comprising a chiller interconnecting the thermal energy storage and the heat rejection apparatus; and
wherein, with the coolant distribution unit in the thermal energy storage charging mode, the chiller and heat rejection apparatus operate to charge the thermal energy storage.

17. The coolant distribution unit of claim 1 wherein the rapid response cooling apparatus includes a thermal energy storage;
a chiller;
wherein the coolant distribution unit has a thermal energy storage charging mode wherein the chiller charges the thermal energy storage.

18. The coolant distribution unit of claim 17 wherein the coolant distribution unit has a thermal energy storage discharge mode wherein the thermal energy storage provides cooling to the facility loop process fluid.

19. The coolant distribution unit of claim 1 further comprising a secondary heat exchanger operable to provide an intermediate process fluid to the rapid response cooling apparatus, the secondary heat exchanger configured to transfer heat between the technical loop process fluid and the intermediate process fluid.

20. The coolant distribution unit of claim 1 in combination with the technical loop, the computers including computer racks.

21. The coolant distribution unit of claim 1 in combination with the facility loop, the facility loop including a cooling tower to remove heat from the facility loop process fluid.

22. The coolant distribution unit of claim 1 wherein the rapid response cooling apparatus comprises a thermal energy storage and/or a chiller.

23. A method of operating a cooling distribution unit including a heat exchanger and a rapid response cooling apparatus, the heat exchanger configured to transfer heat from a process fluid of a technical loop including computers to a process fluid of a facility loop, the method comprising:
detecting a sudden increase of a cooling load of the computers;
causing the rapid response cooling apparatus to contribute to satisfying the increased cooling load of the computers; and
reducing the contribution of the rapid response cooling apparatus to satisfying the cooling load of the computers upon the facility loop being able to satisfy the increased cooling load.

24. The method of claim 23 wherein detecting the sudden increase of the cooling load of the computers includes detecting the sudden increase of the cooling load based at least in part upon the cooling load exceeding a threshold cooling load for a predetermined time period.

25. The method of claim 23 wherein detecting the sudden increase of the cooling load of the computers comprises detecting the sudden increase of the cooling load via a sensor of the technical loop, the sensor configured to detect a parameter of the technical loop that is indicative of the cooling load of the computers.

26. The method of claim 25 wherein the parameter comprises:
a parameter indicative of electrical power consumption of the computers; and/or
a parameter indicative of a temperature of the technical loop.

27. The method of claim 23 wherein detecting the sudden increase of the cooling load of the computers comprises detecting the sudden increase of the cooling load while the facility loop is unable to satisfy the increased cooling load.

28. The method of claim 23 wherein the facility loop requires a period of time of at least two minutes following the sudden increase in the cooling load of the computers before the facility loop is able to satisfy the increased cooling load; and
wherein causing the rapid response cooling apparatus to contribute to satisfying the sudden increase of the cooling load of the computers comprises causing the rapid response cooling apparatus to contribute to satisfying the sudden increase of the cooling load for at least the period of time.

29. The method of claim 23 wherein the facility loop has a normal operating condition and a reduced operating condition, the heat exchanger facilitating a first rate of heat exchange between the technical loop process fluid and the facility loop process fluid when the facility loop is in the normal operation condition that is greater than a second rate of heat exchange between the technical loop process fluid and the facility loop process fluid when the facility loop is in the reduced operating condition; and
wherein causing the rapid response cooling apparatus to contribute to satisfying the increased cooling load of the computers comprises causing the rapid response cooling apparatus to contribute to satisfying the increased cooling load while the facility loop is in the reduced operating condition.

30. The method of claim 23 wherein causing the rapid response cooling apparatus to contribute to satisfying the increased cooling load of the computers comprises the rapid response cooling apparatus absorbing heat from at least one of the technical loop process fluid and the facility loop process fluid.

31. The method of claim 23 wherein causing the rapid response cooling apparatus to contribute to satisfying the increased cooling load of the computers comprises the rapid response cooling apparatus supplementing the heat exchanger transferring heat from the technical loop process fluid to the facility loop process fluid.

32. The method of claim 23 wherein the rapid response cooling apparatus includes a thermal energy storage, the method further comprising recharging the thermal energy storage using at least one of the technical loop process fluid and the facility loop process fluid.

33. The method of claim 23 wherein the rapid response cooling apparatus includes a thermal energy storage, wherein reducing the contribution of the thermal energy storage comprises reducing the contribution of the thermal energy storage based at least in part upon at least one of:
a state of the thermal energy storage;
a predetermined period of time; and
a threshold cooling load.

34. The method of claim 23 wherein the rapid response cooling apparatus includes a thermal energy storage, the method further comprising causing the thermal energy storage to contribute to cooling the facility loop during a peak cooling period of the facility loop.
